(19) United States
(12) Patent Application Publication
(10) Pub. No.: US 2019/0348511 A1
(43) Pub. Date: Nov. 14, 2019

(54) CAP LAYER FOR METAL CONTACTS OF A SEMICONDUCTOR DEVICE

(71) Applicant: INTEL CORPORATION, Santa Clara, CA (US)

(72) Inventors: Elijah V. KARPOV, Portland, OR (US); Dan S. LAVRIC, Portland, OR (US); David J. TOWNER, Portland, OR (US)

(73) Assignee: Intel Corporation, Santa Clara, CA (US)

(21) Appl. No.: 16/474,440

(22) PCT Filed: Mar. 31, 2017
(86) PCT No.: PCT/US2017/025279

§ 371 Date: Jun. 27, 2019

(51) Int. Cl. H01L 29/417; H01L 29/45; H01L 27/088; H01L 29/78; H01L 29/423; H01L 21/8234

(52) U.S. Cl. CPC H01L 29/41791; H01L 29/45; H01L 27/0886; H01L 21/823475; H01L 29/42392; H01L 21/823431; H01L 29/7851

(57) ABSTRACT

Techniques are disclosed for forming transistors including a conductive cap layer formed on metal contacts to help protect the metal contacts from undesired oxidation. The cap layer includes an oxygen barrier layer that includes chromium (Cr) and/or iridium (Ir) to protect the underlying metal contacts (e.g., source/drain contacts) from being exposed to oxygen in the environment during subsequent processing after the metal contacts have been formed. Thus, the cap layer enables the use of hygroscopic and/or highly reactive metals in the metal contacts, such as rare earth metals (e.g., ytterbium, erbium, and yttrium). In some cases, the cap layer includes a diffusion barrier layer between the oxygen barrier layer and a corresponding metal contact to help prevent undesired intermixing of the materials included in the two features. For example, if the oxygen barrier layer includes iridium, a diffusion barrier layer may be employed to prevent undesired intermetallics from forming.

### BACKGROUND

Semiconductor devices are electronic components that exploit the electronic properties of semiconductor materials, such as silicon, germanium, and gallium arsenide. A field-effect transistor (FET) is a semiconductor device that includes three terminals: a gate, a source, and a drain. A FET uses an electric field applied by the gate to control the electrical conductivity of a channel through which charge carriers (e.g., electrons or holes) flow from the source to the drain. In instances where the charge carriers are electrons, the FET is referred to as an n-channel device, and in instances where the charge carriers are holes, the FET is referred to as a p-channel device. Some FETs have a fourth terminal called the body or substrate, which can be used to bias the transistor. In addition, metal-oxide-semiconductor FETs (MOSFETs) include a gate dielectric between the gate and the channel. MOSFETs may also be known as metal-insulator-semiconductor FETs (MISFETSs) or insulated-gate FETs (IGFETs). Complementary MOS (CMOS) structures use a combination of p-channel MOSFET (p-MOS) and n-channel MOSFET (n-MOS) to implement logic gates and other digital circuits.

A FinFET is a MOSFET transistor built around a thin strip of semiconductor material (generally referred to as a fin). The conductive channel of the FinFET device resides on the outer portions of the fin adjacent to the gate dielectric. Specifically, current runs along/within both sidewalls of the fin (sides perpendicular to the substrate surface) as well as along the top of the fin (side parallel to the substrate surface). Because the conductive channel of such configurations essentially resides along the three different outer, planar regions of the fin, such a FinFET design is sometimes referred to as a tri-gate transistor. Other types of FinFET configurations are also available, such as so-called double-gate FinFETs, in which the conductive channel principally resides only along the two sidewalls of the fin (and not along the top of the fin). A nanowire transistor (sometimes referred to as a gate-all-around (GAA) or nanoribbon transistor) is configured similarly to a fin-based transistor, but instead of a finned channel region where the gate is on three portions (and thus, there are three effective gates), one or more nanowires are used for the channel region and the gate material generally surrounds each nanowire.

### BRIEF DESCRIPTION OF THE DRAWINGS

FIG. 1 illustrates a method of forming an integrated circuit (IC) including one or more transistors employing a cap layer for metal contacts, specifically, for metal source/drain (S/D) contacts, in accordance with some embodiments of the present disclosure.

FIGS. 2A-L illustrate example IC structures that are formed when carrying out the method of FIG. 1, in accordance with some embodiments.

FIG. 2C′ is a blown-out portion of FIG. 2C illustrating alternative recess and replace processing to form a replacement material fin, in accordance with some embodiments.

FIG. 2D′ is a blown-out portion of FIG. 2D illustrating the replacement fin from FIG. 2C′ after the shallow trench isolation (STI) material has been recessed, in accordance with some embodiments.

FIG. 2F′ is a blown-out portion of FIG. 2F, illustrating an alternative rounded S/D region that may be formed, in accordance with some embodiments.

FIG. 2F″ is a blown-out portion of FIG. 2F, illustrating a final S/D region that is alternatively formed using a cladding scheme, in accordance with some embodiments.

FIG. 2H′ is a blown-out portion of FIG. 2H, illustrating an alternative rounded S/D region that may be formed, in accordance with some embodiments.

FIG. 3A illustrates an example cross-sectional view along the plane A-A in FIG. 2K, in accordance with some embodiments.

FIG. 3B illustrates the cross-sectional view of FIG. 3A, showing a variation where the diffusion barrier layer is not present in the contact cap layer, in accordance with some embodiments.

FIG. 3C illustrates the cross-sectional view of FIG. 3A, showing a variation where an additional diffusion barrier layer is present between the oxygen barrier layer and the interconnect layer, in accordance with some embodiments.

FIG. 4 illustrates a computing system implemented with integrated circuit structures and/or transistor devices formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. Further still, some of the features in the drawings may include a patterned and/or shaded fill, which is merely provided to assist in visually differentiating the different features. In short, the figures are provided merely to show example structures.

### DETAILED DESCRIPTION

Electrical access to source and drain (S/D) regions of a transistor is gained through metal contacts. Such metal contacts are generally electrically accessed through interconnections formed after the transistor and contacts have been formed. The interconnections generally include metal (e.g., copper) wiring that is formed in dielectric material in any number of back-end-of-line (BEOL) metallization layers. A metal contact may also be used to gain electrical access to a gate structure, in some cases. However, after metal contacts have been formed, they are exposed to oxygen from the environment during subsequent processing (e.g., during various thermal, etch, and deposition processes). Exposure to oxygen in the environment for standard metal contacts causes oxidation of those standard metal contacts, which leads to increased resistance from the oxidized portions of the metal contacts. Such increased contact resistance (e.g., between the metal contact and the metal interconnect) results in an undesired degradation of transistor device performance.

Thus, and in accordance with numerous embodiments of the present disclosure, techniques are provided for forming transistors including a cap layer for metal contacts. In some embodiments, the cap layer may be or include an oxygen barrier layer that includes chromium (Cr) and/or iridium (Ir) to protect underlying metal contacts (e.g., S/D contacts) from oxidation during exposure to the environment after the metal contact has been formed. Chromium and iridium are particularly well-suited for such an oxygen barrier layer, because of their high corrosion-inhibiting properties. For instance, iridium is the most corrosion-resistant metal, even at temperatures as high as 2000 degrees Celsius. In addition, the oxygen barrier layer can remain in the final integrated circuit structure, as it is a conductive layer that can effectively exist between a metal contact and its corresponding metal interconnect, as will be apparent in light of this disclosure. In some embodiments, the oxygen barrier layer may enable the use of (or the improved use of) particular metal contact materials, such as the use of hygroscopic and/or highly reactive metals. For instance, the oxygen barrier layer may be used to benefit contacts including one or more rare earth metals, such as cerium (Ce), gadolinium (Gd), terbium (Tb), erbium (Er), ytterbium (Yb), and/or yttrium (Y), to provide some examples. Rare earth metal contacts may be desired for n-type doped semiconductor regions (e.g., n-type S/D regions, such as for n-MOS devices), where the rare earth metal included in a given contact may provide an effective low work-function metal contact for the transistor device. However, rare earth metals are also more susceptible to oxidation. Therefore, in some embodiments, a chromium and/or iridium-based oxygen barrier layer may be employed in a cap layer above the metal contact to provide an enhanced barrier to oxidation of that metal contact. In other words, the oxygen barrier layer as described herein can be used to protect a given underlying metal contact from converting, in part, to electrical insulator material (e.g., to help prevent the formation of thin films of oxide material on the top/exposed surface of the metal contact), thereby improving contact resistance and enhancing the overall device performance.

In some embodiments, the oxygen barrier layer includes chromium (Cr), such as including only chromium or a chromium-based alloy, to help reduce oxidation of underlying metal contacts. In embodiments where a chromium-based alloy is employed, the chromium may be alloyed with at least one of cobalt (Co), nickel (Ni), and molybdenum (Mo), to provide a few examples. In some such embodiments, the chromium-based alloy may have a chromium concentration (by atomic percentage) in the range of 1-50% (or in a subrange of 1-10, 1-20, 1-30, 1-40, 5-10, 5-20, 5-30, 5-40, 5-50, 10-20, 10-30, 10-40, 10-50, 20-30, 20-40, 20-50, or 30-50%), or any other suitable value or range as will be apparent in light of this disclosure. Further, in embodiments where the oxygen barrier layer includes a chromium-based alloy, that chromium-based alloy may include less than 50, 40, 30, 25, 20, 15, 10, or 5% chromium concentration (by atomic percentage), for example. In embodiments where a chromium-based oxygen barrier layer is being used to protect a metal contact including one or more rare earth metals, such ytterbium, erbium, and/or yttrium, the oxygen barrier layer may be formed directly on that rare earth metal-based contact, as chromium can be in direct contact with rare earth metals without significant concern that the chromium and rare earth metal material will intermix (which is atypical for most metals). The lack of intermixing in such embodiments is helpful, because it avoids an intermetallic region that, if present, undesirably leads to increased contact resistance and/or to deterioration of the barrier property of the oxygen barrier layer, thereby leading to degradation of the overall device performance. However, in some embodiments, a diffusion barrier (or chemical barrier) layer may be employed between a chromium-based oxygen barrier layer and the underlying metal contact to, for example, help prevent intermixing of the chromium and the material of the metal contact, thereby helping to prevent an undesired intermetallic region of the chromium and metal contact material. For instance, in some such embodiments, the diffusion barrier layer may include titanium (Ti), to provide an example. As can be understood based on this disclosure, in some embodiments, a diffusion barrier layer need not be employed for oxygen barrier layers including chromium, such as when using the chromium-based oxygen barrier layer to cap a rare earth metal contact.

In some embodiments, the oxygen barrier layer includes iridium (Ir), such as including only iridium or an iridium-based alloy, to help reduce oxidation of underlying metal contacts. As previously described, iridium is the most corrosion-resistant metal, and iridium is also very dense, which helps prevent undesired atom penetration (e.g., of oxygen atoms) therethrough. In addition, iridium is a noble metal, and thus, it does not form insulating oxide. Further, iridium has a relatively high melting temperature (approximately 2447 degrees Celsius), and thus, a relatively low homologous temperature, allowing for it to be desirably formed as a thin and smooth film for the purposes of an oxygen barrier layer. In embodiments where an iridium-based alloy is employed, the iridium may be alloyed with at least one of cobalt (Co), nickel (Ni), and hafnium (Hf), to provide a few examples. In some such embodiments, the iridium-based alloy may have any iridium concentration (by atomic percentage), such as a concentration in the range of 1-99% (or in a subrange of 1-25, 1-50, 1-75, 10-25, 10-50, 10-75, 10-99, 25-50, 25-75, 25-99, 50-75, or 50-99%), for example. For instance, in embodiments where the oxygen barrier layer includes an iridium-based alloy, that iridium-based alloy may include less than or greater than 5, 10, 20, 30, 40, 50, 60, 70, 80, or 90% iridium concentration (by atomic percentage), depending on the given configuration. Note that in embodiments where the oxygen barrier layer includes an iridium-hafnium alloy, the iridium concentration (by atomic percentage) may be selected to be in the range of 10-20%, for example. Also note that, generally, for any oxygen barrier layer including an alloy configuration (e.g., chromium-based alloy or iridium-based alloy), the oxygen barrier properties may be degraded. Therefore, in some embodiments, it may be desired to use a chromium layer or an iridium layer for the oxygen barrier layer. However, alloying may be desired from a cost perspective as, for example, iridium, is generally an expensive material (but such cost has to be balanced with alloy processing, which generally adds to and/or complicates the processing).

In some embodiments, a diffusion barrier layer may be employed between an iridium-based oxygen barrier layer and the underlying metal contact to, for example, help prevent intermixing between the iridium and the material of the metal contact. For instance, in embodiments where an iridium-based oxygen barrier layer is being used to protect a metal contact including one or more rare earth metals, such ytterbium, erbium, and/or yttrium, it may be undesirable to form the iridium-based oxygen barrier layer directly on that rare earth metal-based contact, because the metal of the contact structure may intermix and diffuse into the iridium of the oxygen barrier layer. Such intermixing and diffusion causes an intermetallic region that is undesirable, as it leads to degraded performance for the contact structure and/or can hurt the oxygen barrier properties of the iridium-based layer. Thus, in some such embodiments, a diffusion barrier layer can be employed to reduce or prevent such intermixing/diffusion. In some embodiments, a diffusion barrier layer may be employed between an iridium-based oxygen barrier layer and a corresponding metal contact, where the diffusion barrier layer may include at least one of rhenium (Re), tungsten (W), and tantalum (Ta), to provide some examples. For instance, such a diffusion barrier layer may help prevent rare earth metals (where included in the metal contact) from undesirably diffusing into the iridium-based oxygen barrier layer. In some embodiments, a diffusion barrier layer may also or alternatively be employed between an iridium-based oxygen barrier layer and the metal contact and/or between the iridium-based oxygen barrier layer the overlying metal interconnect to help prevent iridium diffusion into those adjacent metal features (into the metal contact and/or the metal interconnect). In some such embodiments, the diffusion barrier layer may include carbon (C), silver (Ag), hafnium (Hf), and/or a metal nitride (e.g., tantalum nitride (TaN), titanium nitride (TiN)) to act as a barrier and help prevent outdiffusion of the iridium. Thus, in some embodiments, the diffusion barrier layer between an iridium-based oxygen barrier layer and its corresponding metal contact may include a multilayer structure to help prevent outdiffusion of rare earth metal (where employed) from the metal contact and to help prevent outdiffusion of the iridium from the oxygen barrier layer. Generally, in any embodiment employing multiple diffusion barrier layers for a given oxygen barrier layer, an example scheme may include the following electrical flow: semiconductor S/D region—metal contact—first diffusion barrier layer—oxygen barrier layer—second diffusion barrier layer—metal interconnect, where the first diffusion barrier layer may or may not have a multilayer structure. However, in some embodiments, a diffusion barrier layer need not be employed for an iridium-based oxygen barrier layer, such as in embodiments where the iridium-based oxygen barrier layer is protecting a high work-function metal contact for a p-type doped semiconductor region (e.g., a p-type S/D region, such as for a p-MOS device), to provide an example configuration.

Thus, as can be understood based on this disclosure, in some embodiments, the techniques include forming a cap layer for one or more metal contacts where the cap layer just includes an oxygen barrier layer as described herein, while in other embodiments, the techniques include forming a cap layer including an oxygen barrier layer and one or more diffusion barrier layers as described herein. In other words, the cap layer may or may not include a multilayer structure, depending on the particular configuration employed. In some embodiments, the cap layer (including, at least, the oxygen barrier layer), may be formed in the same contact trench as the metal contact it is protecting, after the metal contact has been formed. In some such embodiments, the processing may be performed in-situ (without air break) to prevent the top of the metal contact from being exposed to oxygen in the atmosphere prior to forming the cap layer, for example. However, numerous different processing configurations and variations will be apparent in light of this disclosure. In some embodiments, the oxygen barrier layer may have a thickness in the range of 2-30 nm (or in a sub-range of 2-5, 2-10, 2-15, 2-20, 5-10, 5-15, 5-20, 5-30, 10-15, 10-20, or 10-30 nm), or any other suitable value or range as will be apparent in light of this disclosure. In some embodiments, a given diffusion barrier layer, where present, may have a thickness in the range of 2-30 nm (or in a sub-range of 2-5, 2-10, 2-15, 2-20, 5-10, 5-15, 5-20, 5-30, 10-15, 10-20, or 10-30 nm), or any other suitable value or range as will be apparent in light of this disclosure. Thus, in some embodiments, the cap layer can be maintained as a relatively thin layer that includes one or more layers.

As can be understood based on this disclosure, the techniques can be implemented for transistors including group IV semiconductor material, group III-V semiconductor material, and/or any other suitable semiconductor material. The use of “group IV semiconductor material” (or “group IV material” or generally, “IV”) herein includes at least one group IV element (e.g., silicon, germanium, carbon, tin), such as silicon (Si), germanium (Ge), silicon germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), and so forth. Note that group III may also be known as the boron group or IUPAC group 13, group IV may also be known as the carbon group or IUPAC group 14, and group V may also be known as the nitrogen family or IUPAC group 15, for example. For instance, in some embodiments, the techniques can be used to benefit transistors including channel material that includes at least one of silicon (Si), germanium (Ge), tin (Sn), indium (In), gallium (Ga), arsenic (As), phosphorous (P), and aluminum (Al), to provide some examples. Also note that the techniques can be used to benefit numerous different metal contacts, where such metal contacts include one or more metal materials (e.g., a pure metal or a metal alloy), as will be apparent in light of this disclosure.

In some embodiments, the techniques can be used to benefit a multitude of transistor devices. For instance, in some embodiments, the techniques may be used to benefit metal-oxide-semiconductor field-effect transistors (MOSFETs), tunnel FETs (TFETs), fermi-filter FETs (FFFETs), and/or any other suitable FET or transistor device, as can be understood based on this disclosure. Further, in some embodiments, the techniques may be used to benefit one or more n-channel transistor devices (where the charge carriers are electrons) and/or p-channel transistor devices (where the charge carriers are holes), such as n-channel MOSFET (n-MOS) devices and/or p-channel MOSFET (p-MOS) devices. In some embodiments, the techniques described herein can be used to benefit complementary transistor circuits, such as CMOS circuits, where the techniques can be used to benefit one or more of the included n-channel transistors (e.g., n-MOS devices) and/or p-channel transistors (e.g., p-MOS devices) making up a given CMOS circuit. Further still, in some embodiments, the techniques described herein can be used to benefit transistors including a multitude of configurations, such as planar and non-planar configurations, where the non-planar configurations may include finned or FinFET configurations (e.g., dual-gate or tri-gate), gate-all-around (GAA) configurations (e.g., nanowire or nanoribbon), or some combination thereof (e.g., beaded-fin configurations), to provide a few examples. Other example transistor devices that can benefit from the techniques described herein include few to single electron quantum transistor devices, for example.

In general, the techniques can be used to benefit metal contacts that are electrically and/or physically in contact with (or otherwise connected to) n-type doped semiconductor regions and/or p-type doped semiconductor regions (e.g., n-type and/or p-type S/D regions). However, in some embodiments, the techniques may be particularly well suited for metal contacts that make contact to n-type doped semiconductor regions (e.g., n-type S/D regions), as a cap layer as described herein may enable the use of novel metal materials for contacts, such as hygroscopic and/or highly reactive metals, which include rare earth metals. As previously described, a rare earth metal may be used as a low work-function contact metal for a given n-type doped semiconductor region (e.g., an n-type S/D region, such as for an n-MOS device). Rare earth metals include the following elements: cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y). Note that although the techniques are primarily depicted and described herein in the context of forming a cap layer for both S/D contacts of a given transistor, the present disclosure is not intended to be so limited. For instance, in some embodiments, the techniques may be used to only benefit the source contact of a given transistor or the drain contact of a given transistor, for example.

Note that, as used herein, the expression “X includes at least one of A and B” refers to an X that may include, for example, just A only, just B only, or both A and B. To this end, an X that includes at least one of A and B is not to be understood as an X that requires each of A and B, unless expressly so stated. For instance, the expression “X includes A and B” refers to an X that expressly includes both A and B. Moreover, this is true for any number of items greater than two, where “at least one of” those items is included in X. For example, as used herein, the expression “X includes at least one of A, B, and C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, and C is not to be understood as an X that requires each of A, B, and C, unless expressly so stated. For instance, the expression “X includes A, B, and C” refers to an X that expressly includes each of A, B, and C.

Use of the techniques and structures provided herein may be detectable using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDS); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate an integrated circuit (IC) including at least one transistor that includes a cap layer as described herein for one or both of the source/drain (S/D) metal contacts. In some such embodiments, the cap layer includes a layer including chromium and/or iridium (referred to herein as an oxygen barrier layer) and may also optionally include a diffusion barrier layer that may be employed to help prevent intermixing between the oxygen barrier layer and the corresponding metal contact. In some embodiments, the techniques and structures described herein may be detected based on the benefits derived therefrom, such as being able to use (or more effectively use) rare earth metals in S/D contacts for n-type S/D regions, for example. Further, in some embodiments, the techniques described herein may enable forming enhanced performance transistor devices with sub-50 nm gate lengths (or gate lengths below some other suitable threshold as will be apparent in light of this disclosure), which can also be detected and measured.

Note that although the techniques and the metal contact cap layer are primarily depicted and described herein in the context of transistor devices, and more specifically, in the context of benefiting one or both S/D contacts of one or more transistor devices, the present disclosure is not intended to be so limited. For instance, in other embodiments, the cap layer as described herein may be employed for metal contacts (e.g., that make electrical connection to semiconductor material) of other semiconductor devices, such as diodes, capacitors, and/or sensors, to provide some examples. Numerous configurations and variations will be apparent in light of this disclosure.

Architecture and Methodology

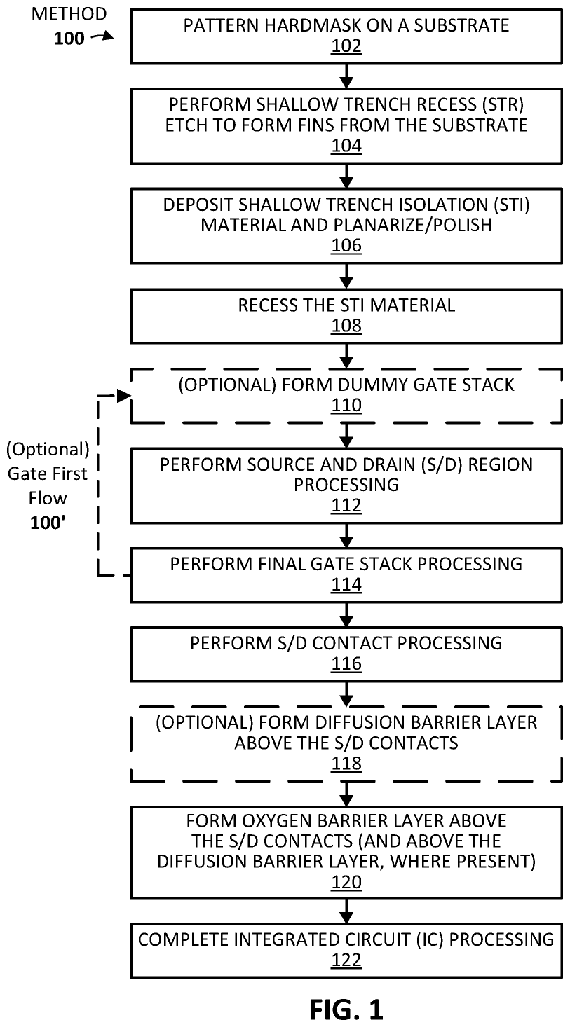

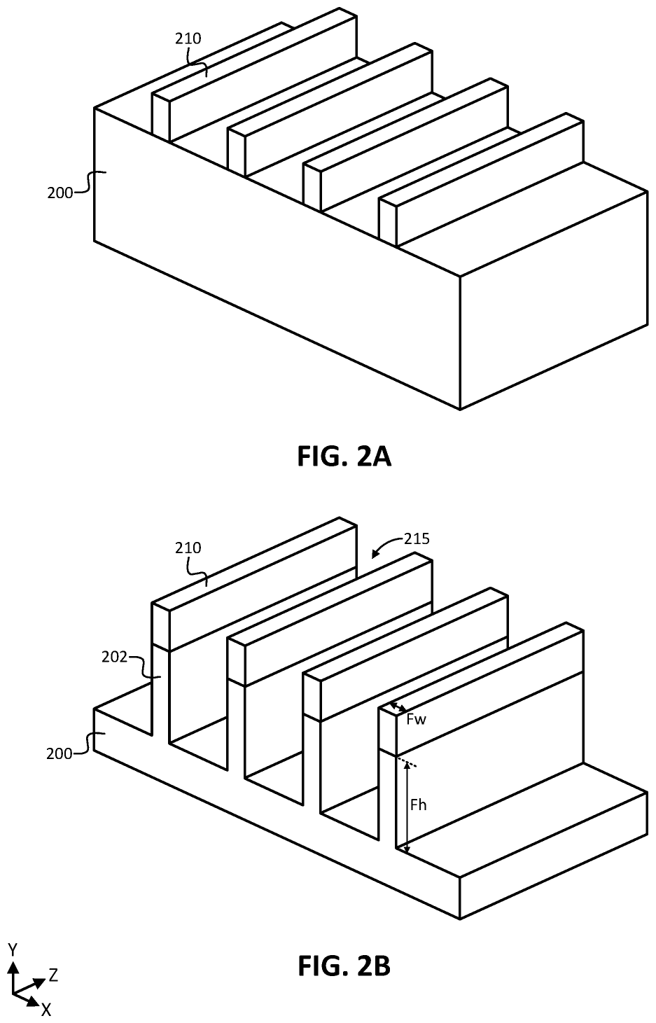

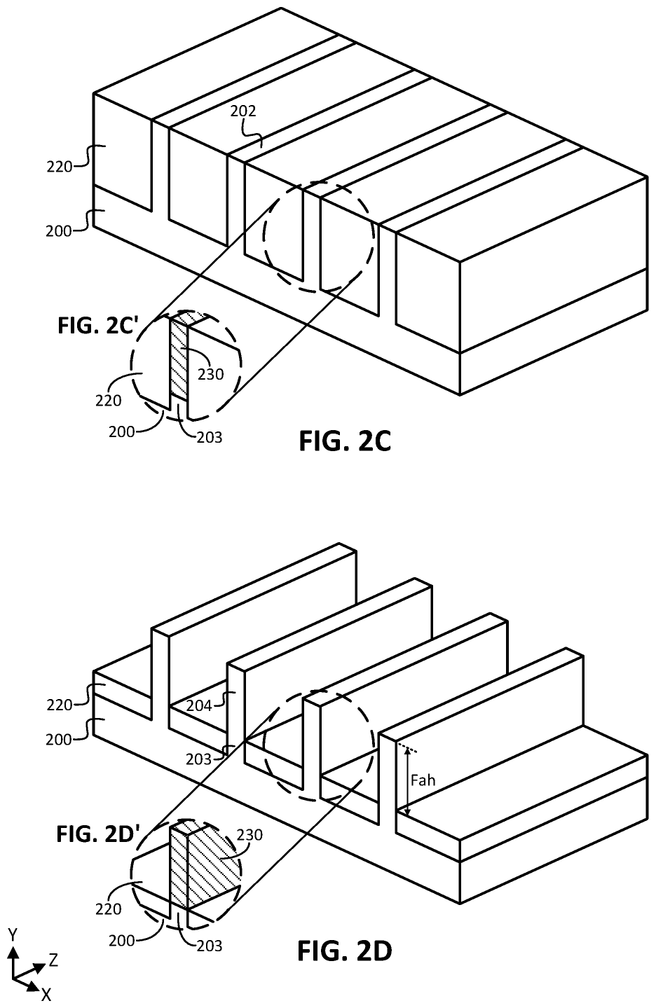

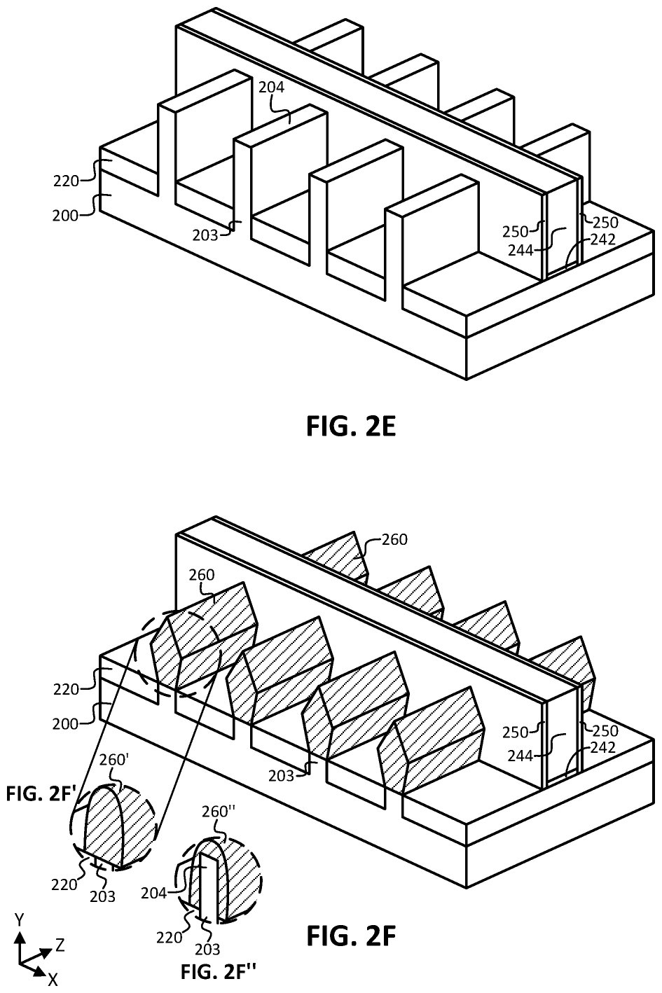

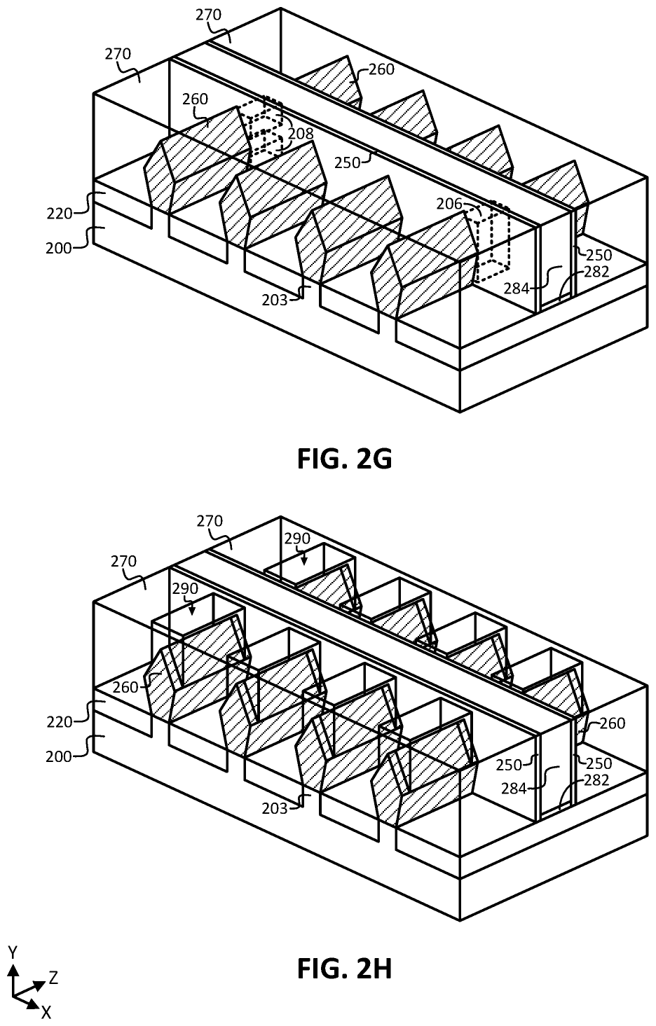

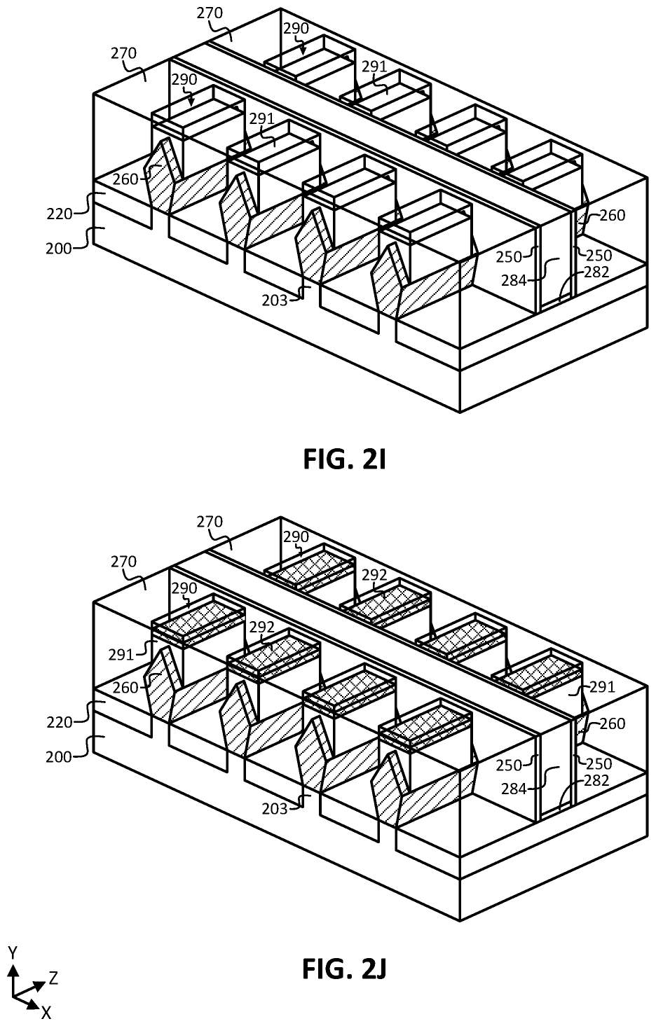

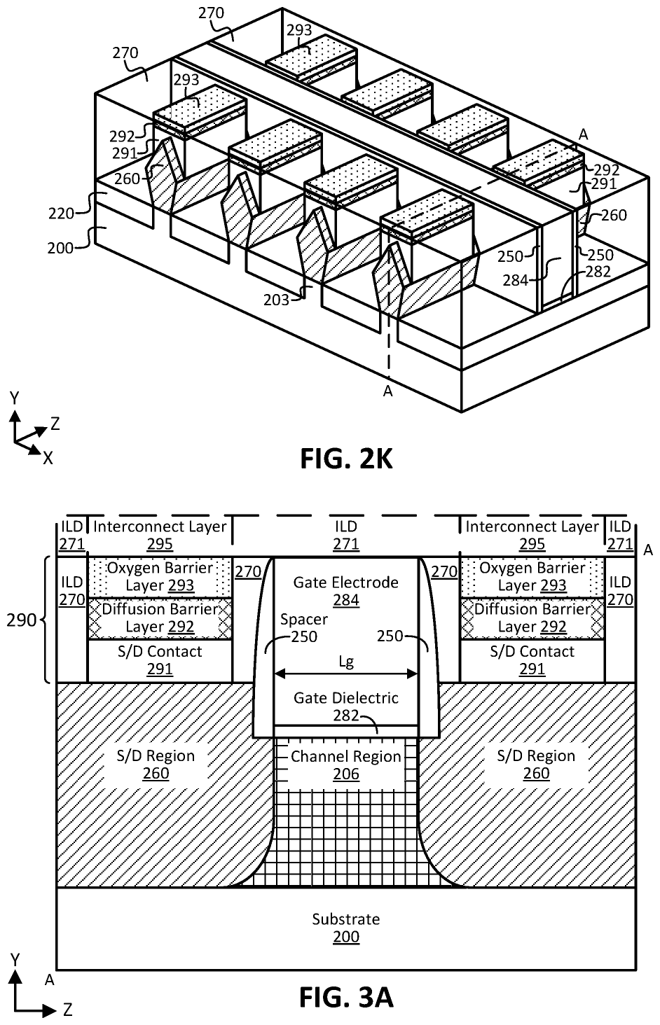

FIG. 1 illustrates method 100 of forming an integrated circuit (IC) including one or more transistors employing a cap layer for metal contacts, specifically, for metal source/drain (S/D) contacts, in accordance with some embodiments of the present disclosure. FIGS. 2A-L illustrate example IC structures that are formed when carrying out method 100 of FIG. 1, in accordance with some embodiments. The structures of FIGS. 2A-L are primarily depicted and described herein in the context of forming finned or FinFET transistor configurations (e.g., tri-gate transistor configurations), for ease of illustration. However, in some embodiments, the techniques can be used to form transistors of any suitable geometry or configuration, as can be understood based on this disclosure. For example, FIG. 2G illustrates an example IC structure including a transistor having a nanowire configuration, as will be described in more detail below. Also note that the techniques and structures are primarily depicted and described in the context of forming metal-oxide-semiconductor field-effect transistors (MOSFETs). However, the present disclosure is not intended to be so limited unless stated otherwise. Further note that method 100 includes a primary path that illustrates a gate last transistor fabrication process flow, in accordance with some embodiments. However, in other embodiments, a gate first process flow may be used, as will be described herein (and which is illustrated with the alternative gate first flow 100′ indicator in FIG. 1). Numerous variations and configurations will be apparent in light of this disclosure.

A multitude of different transistors and transistor-based devices can benefit from the techniques described herein, which may include, but are not limited to, various different field-effect transistors (FETs), such as metal-oxide-semiconductor FETs (MOSFETs), tunnel FETs (TFETs), and Fermi filter FETs (FFFETs), to name a few examples. For example, the techniques may be used to benefit one or both of the S/D contacts of an n-channel MOSFET (n-MOS) device, which may include a source-channel-drain doping scheme of n-p-n or n-i-n, where ‘n’ indicates n-type doped semiconductor material, ‘p’ indicates p-type doped semiconductor material, and T indicates intrinsic/undoped semiconductor material (which may also include nominally undoped semiconductor material, including dopant concentrations of less than 1E16 atoms per cubic centimeter (cm), for example), in accordance with some embodiments. In another example, the techniques may be used to benefit one or both of the S/D contacts of a p-channel MOSFET (p-MOS) device, which may include a source-channel-drain doping scheme of p-n-p or p-i-p, in accordance with some embodiments. In yet another example, the techniques may be used to benefit one or both of the S/D contacts of a TFET device, which may include a source-channel-drain doping scheme of p-i-n or n-i-p, in accordance with some embodiments. In still another example, the techniques may be used to benefit one or both of the S/D contacts of a FFFET device, which may include a source-channel-drain doping scheme of np-i-p (or np-n-p) or pn-i-n (or pn-p-n), in accordance with some embodiments. Further, the techniques may be used to benefit complementary transistor circuits, such as CMOS circuits, where the techniques may be used to benefit one or more of the included n-channel and/or p-channel transistors making up the CMOS circuit. Other example transistor devices that can benefit from the techniques described herein include few to single electron quantum transistor devices, in accordance with some embodiments. Further still, any such devices may employ semiconductor materials that are three-dimensional crystals as well as two dimensional crystals or nanotubes, for example. In some embodiments, the techniques may be used to benefit devices of varying scales, such as IC devices having critical dimensions in the micrometer (micron) range and/or in the nanometer (nm) range (e.g., formed at the 22, 14, 10, 7, 5, or 3 nm process nodes, or beyond).

Method 100 of FIG. 1 includes patterning 102 hardmask on a substrate, such as patterning hardmask 210 on substrate 200 to form the example structure of FIG. 2A, in accordance with some embodiments. In some embodiments, hardmask 210 may be deposited or otherwise formed on substrate 200 using any suitable techniques as will be apparent in light of this disclosure. For example, hardmask 210 may be blanket deposited or otherwise grown on substrate 200 using chemical vapor deposition (CVD), atomic layer deposition (ALD), physical vapor deposition (PVD), spin-on processing, and/or any other suitable process to form hardmask 210 on substrate 200. In some instances, the top surface of substrate 200 on which hardmask 210 is to be deposited may be treated (e.g., via chemical treatment, thermal treatment, etc.) prior to deposition of the hardmask 210 material. After being blanket formed on substrate 200, hardmask 210 may then be patterned using any suitable techniques, such as one or more lithography and etch processes, for example. Hardmask 210 may include any suitable material, such as oxide material, nitride material, and/or any other suitable dielectric/electrical insulator material, for example. Specific oxide and nitride materials may include silicon oxide, titanium oxide, hafnium oxide, aluminum oxide, silicon nitride, and titanium nitride, just to name a few examples. In some cases, the material of hardmask 210 may be selected based on the material of substrate 200, for example.

Substrate 200, in some embodiments, may be: a bulk substrate including group IV semiconductor material, such as silicon (Si), germanium (Ge), silicon germanium (SiGe), or silicon carbide (SiC), group III-V semiconductor material, and/or any other suitable material(s) as will be apparent in light of this disclosure; an X on insulator (XOI) structure where X is one of the aforementioned materials (e.g., group IV and/or group III-V semiconductor material) and the insulator material is an oxide material or dielectric material or some other electrically insulating material, such that the XOI structure includes the electrically insulating material layer between two semiconductor layers; or some other suitable multilayer structure where the top layer includes one of the aforementioned semiconductor materials (e.g., group IV and/or group III-V semiconductor material). The use of “group IV semiconductor material” (or “group IV material” or generally, “IV”) herein includes at least one group IV element (e.g., silicon, germanium, carbon, tin), such as silicon (Si), germanium (Ge), silicon germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), and so forth. Note that group III may also be known as the boron group or IUPAC group 13, group IV may also be known as the carbon group or IUPAC group 14, and group V may also be known as the nitrogen family or IUPAC group 15, for example.

In some embodiments, substrate 200 may be doped with any suitable n-type and/or p-type dopant. For instance, in the case, of a Si substrate, the Si may be p-type doped using a suitable acceptor (e.g., boron) or n-type doped using a suitable donor (e.g., phosphorous, arsenic), to provide some example cases. However, in some embodiments, substrate 200 may be undoped/intrinsic or relatively minimally doped (such as including a dopant concentration of less than 1E16 atoms per cubic cm), for example. In some embodiments, substrate 200 may include a surface crystalline orientation described by a Miller index of (100), (110), or (111), or its equivalents, as will be apparent in light of this disclosure. Although substrate 200, in this example embodiment, is shown as having a thickness (dimension in the Y-axis direction) similar to other layers shown in subsequent structures for ease of illustration, in some instances, substrate 200 may be much thicker than the other layers, such as having a thickness in the range of 50 to 950 microns, for example, or any other suitable thickness as will be apparent in light of this disclosure. In some embodiments, substrate 200 may be used for one or more other IC devices, such as various diodes (e.g., light-emitting diodes (LEDs) or laser diodes), various transistors (e.g., MOSFETs or TFETs), various capacitors (e.g., MOSCAPs), various microelectromechanical systems (MEMS), various nanoelectromechanical systems (NEMS), various radio frequency (RF) devices, various sensors, or any other suitable semiconductor or IC devices, depending on the end use or target application. Accordingly, in some embodiments, the structures described herein may be included in a system-on-chip (SoC) application, as will be apparent in light of this disclosure.

Method 100 of FIG. 1 continues with performing 104 shallow trench recess (STR) etch to form fins 202 from substrate 200, thereby forming the resulting example structure shown in FIG. 2B, in accordance with some embodiments. In some embodiments, the STR etch 104 used to form trenches 215 and fins 202 may include any suitable techniques, such as various masking processes and wet and/or dry etching processes, for example. In some cases, STR etch 104 may be performed in-situ/without air break, while in other cases, STR etch 104 may be performed ex-situ, for example. Trenches 215 may be formed with varying widths (dimension in the X-axis direction) and depths (dimension in the Y-axis direction) as can be understood based on this disclosure. For example, multiple hardmask patterning 102 and STR etching 104 processes may be performed to achieve varying depths in the trenches 215 between fins 202. Fins 202 may be formed to have varying widths Fw (dimension in the X-axis direction) and heights Fh (dimension in the Y-axis direction). Note that although hardmask structures 210 are still present in the example structure of FIG. 2B, in some cases, that need not be the case, as they may have been consumed during the STR etch, for example.

In some embodiments, the fin widths Fw (dimension in the horizontal or X-axis direction) may be in the range of 2-400 nm (or in a subrange of 2-10, 2-20, 2-50, 2-100, 2-200, 4-10, 4-20, 4-50, 4-100, 4-200, 4-400, 10-20, 10-50, 10-100, 10-200, 10-400, 50-100, 50-200, 50-400, or 100-400 nm), for example, or any other suitable value or range as will be apparent in light of this disclosure. In some embodiments, the fin heights Fh (dimension in the vertical or Y-axis direction) may be in the range of 4-800 nm (or in a subrange of 4-10, 4-20, 4-50, 4-100, 4-200, 4-400, 10-20, 10-50, 10-100, 10-200, 10-400, 10-800, 50-100, 50-200, 50-400, 50-800, 100-400, 100-800, or 400-800 nm), for example, or any other suitable value or range as will be apparent in light of this disclosure. In some embodiments, the fin heights Fh may be at least 25, 50, 75, 100, 125, 150, 175, 200, 300, 400, or 500, 600, 700, or 800 nm tall, or greater than any other suitable threshold height as will be apparent in light of this disclosure. In some embodiments, the height to width ratio of the fins (Fh:Fw) may be greater than 1, such as greater than 1.5, 2, 2.5, 3, 3.5, 4, 4.5, 5, 6, 7, 8, 9, or 10, or greater than any other suitable threshold ratio, as will be apparent in light of this disclosure. Note that the trenches 215 and fins 202 are each shown as having essentially the same sizes and shapes in this example structure for ease of illustration; however, the present disclosure is not intended to be so limited. For example, in some embodiments, the fins 202 may be formed to have varying heights Fh, varying widths Fw, varying starting points (or varying starting heights), varying shapes, and/or any other suitable variations as will be apparent in light of this disclosure. Moreover, trenches 215 may be formed to have varying depths, varying widths, varying starting points (or varying starting depths), varying shapes, and/or any other suitable variations as will be apparent in light of this disclosure. Further note that although four fins 202 are shown in the example structure of FIG. 2B for ease of illustration, any number of fins may be formed, such as one, two, three, five, ten, hundreds, thousands, millions, billions, and so forth, as can be understood based on this disclosure.

Method 100 of FIG. 1 continues with depositing 106 shallow trench isolation (STI) material 220 and planarizing/polishing the structure to form the example resulting structure of FIG. 2C, in accordance with some embodiments. In some embodiments, deposition 106 of STI material 220 may include any suitable deposition techniques, such as those described herein (e.g., CVD, ALD, PVD), or any other suitable deposition process. In some embodiments, STI material 220 (which may be referred to as an STI layer) may include any suitable electrically insulating material, such as one or more dielectric, oxide (e.g., silicon dioxide), and/or nitride (e.g., silicon nitride) materials. In some embodiments, the material of STI layer 220 may selected based on the material of substrate 200. For instance, in the case of a Si substrate, the STI material may be selected to be silicon dioxide or silicon nitride, to provide some examples. In some embodiments, the planarizing and/or polishing process(es) performed after forming STI material 220 may include any suitable techniques, such as chemical-mechanical planarization/polishing (CMP) processes, for example.

In embodiments where the fins are to be removed and replaced with replacement semiconductor material (e.g., to be used in the channel region of one or more transistor devices), the structure of FIG. 2C enables such processing. For example, continuing from the structure of FIG. 2C, fins 202 may be recessed or removed using selective etch processing (e.g., for a given etchant, the semiconductor material of fins 202 is removed selective to the insulator material of STI layer 220) to form fin-shaped trenches between STI material 220 in which replacement semiconductor material can be deposited/grown (e.g., using any suitable techniques, such as CVD, metal-organic CVD (MOCVD), ALD, molecular beam epitaxy (MBE), PVD). For instance, FIG. 2C′ is a blown-out portion of FIG. 2C illustrating alternative recess and replace processing to form a replacement material fin, in accordance with some embodiments. In FIG. 2C′, replacement fin 230 was formed, and the replacement fin 230 (and generally, any replacement fin formed) may include any suitable semiconductor material (e.g., group IV and/or III-V semiconductor material). For instance, replacement fins including SiGe or Ge may be formed by removing native Si fins during such processing and replacing them with the SiGe or Ge material, to provide some examples. In addition, replacement fin 230 may include any suitable n-type or p-type dopant. In some embodiments, replacement material fins, such as replacement fin 230 of FIG. 2C′ may be formed using alternative processing. For instance, in some embodiments, replacement material fins may be formed by blanket-growing the replacement material on the substrate (e.g., using epitaxial deposition processing) and then patterning the replacement material into replacement material fins, to provide an example alternative. Such an example alternative process may also include forming STI material between the replacement material fins to form a structure similar to that shown in FIG. 2D′, for instance. Note that replacement fin 230 is illustrated with patterning/shading to merely assist with visually identifying that feature; however, the patterning/shading is not intended to limit the present disclosure in any manner.

Note that only one fin is shown being replaced in the example embodiment of FIG. 2C′; however, the present disclosure is not intended to be so limited. In some embodiments, all of the native fins 202 may be replaced or only a subset may be replaced (e.g., such that some replacement fins are available for subsequent processing and some native fins 202 remain for subsequent processing). Further, in some embodiments, the recess and replace process may be performed as many times as desired to form as many subsets of replacement fins as desired by masking off the areas not to be processes for each replacement fin subset processing. In some such embodiments, a first subset of replacement fins may be formed for n-channel transistors (e.g., where the first replacement material is selected to increase electron mobility) and a second subset of replacement fins may be formed for p-channel transistors (e.g., where the second replacement material is selected to increase hole mobility). Further still, in some embodiments, a multilayer replacement fin may be formed to enable the subsequent formation of nanowires or nanoribbons in the channel region of one or more transistors, where some of the layers in the multilayer replacement fin are sacrificial and intended to be removed via selective etching (e.g., during replacement gate processing), which will be described in more detail herein. Further note that the recess process used to form replacement fin 230 included recessing native fin 202 (i.e., native to substrate 200) to a depth as shown, such that a portion of that native fin 202 remains, which is referred to as sub-fin portion 203 (indicated in FIG. 2C′). However, in other embodiments, the recess process may completely remove a given native fin 202 or recess the given native fin 202 to a different depth (e.g., a different point in the vertical or Y-axis direction).

In embodiments employing an aspect ratio trapping (ART) integration scheme, fins 202 may be formed to have particular height to width ratios such that if they are later removed or recessed (e.g., to form replacement fins 230 in FIG. 2C′), the resulting fin-shaped trenches formed allow for defects in the replacement material deposited to terminate on a side surface as the material grows vertically, such as non-crystalline/dielectric sidewalls, where the sidewalls are sufficiently high relative to the size of the growth area so as to trap most, if not all, of the defects, if such an ART scheme is used. As can be understood in some such embodiments, the channel region material need not be native to substrate 200. In some such embodiments employing an ART scheme, the fins may be formed to have particular height to width ratios (e.g., at least 1.5-5) such that when they are later recessed and/or removed, the resulting fin trenches formed allow for defects in the replacement material deposited to terminate on a side surface as the material grows vertically, such as non-crystalline/dielectric sidewalls, where the sidewalls are sufficiently high relative to the size of the growth area so as to trap most, if not all, of the defects.

Generally, in a trench fill integration scheme, the fins may be formed to have particular height to width ratios (e.g., at least 2-5) such that when they are later removed or recessed, the resulting trenches formed allow the replacement material deposited to grow vertically from the native substrate bottom and be confined by non-crystalline/dielectric sidewalls. The material used to fill these trenches may be sufficiently lattice matched to the substrate (or to a buffer layer used between the substrate and replacement material) such that effectively no relaxation or threading misfit dislocation formation occurs (e.g., the misfit dislocations occur at levels below 1E5 dislocations per square cm). For instance, this lattice match condition is true for native Si fins and trench fill of SiGe replacement material having Ge concentration (by atomic percentage) of less than 45% and fin heights Fh of less than 50 nm, to provide an example. Alternatively, using the Si substrate example (where the native Si fins are recessed to form trenches), a replacement material trench fill of Ge, SiGe with Ge concentration of at least 80%, or GaAs can be performed such that the dislocations form right at the native/replacement material interface and again effectively no threading misfit dislocation formation occurs at the top surface of the replacement material fin (e.g., the misfit dislocations occur at levels below 1E5 dislocations per square cm).

Method 100 of FIG. 1 continues with recessing 108 the STI material 220 to cause at least a portion 204 of fins 202 to exude from the STI plane, thereby forming the resulting example structure shown in FIG. 2D, in accordance with some embodiments. In some embodiments, recessing 112 may be performed using any suitable techniques, such as using one or more wet and/or dry etch processes that allow the STI material 220 to be selectively recessed relative to the material of fin 202, and/or any other suitable processing as will be apparent in light of this disclosure. As can be understood based on this disclosure, fin portions 204 may be used in the active channel region of one or more transistors, such that fin portions 204 (the portions of fins 202 above the top plane of STI layer 220 after recess 108 has been performed) may be referred to as active fin portions herein, for example. Moreover, the remaining portions of fins 202 below the top plane of STI layer 220 are indicated as portions 203, where such portions may be referred to as sub-fin or sub-channel portions, for example.

As shown in FIG. 2D, the portions 204 of fins 202 exuding above the top plane of STI layer 220 have an active fin height indicated as Fah, which may be in the range of 4-800 nm (e.g., in the subrange of 4-10, 4-20, 4-50, 4-100, 4-200, 4-400, 10-20, 10-50, 10-100, 10-200, 10-400, 10-800, 50-100, 50-200, 50-400, 50-800, 100-400, 100-800, or 400-800 nm), for example, or any other suitable value or range, as will be apparent in light of this disclosure. In some embodiments, the active fin heights Fah may be at least 25, 50, 75, 100, 125, 150, 175, 200, 300, 400, 500, 600, 700, or 800 nm tall, or greater than any other suitable threshold height as will be apparent in light of this disclosure. In addition, FIG. 2D′ is a blown-out portion of FIG. 2D illustrating the replacement fin 230 from FIG. 2C′ after the STI material has been recessed, in accordance with some embodiments. Note that in other embodiments, replacement fins 230 may also be formed by blanket depositing the replacement material and forming the replacement material into fins, followed by STI processing, as can be understood based on this disclosure. Also note that in embodiments employing planar transistor configurations, recess process 108 need not be performed, as the transistor may be formed using the top surface of fin 202 from FIG. 2C.

Method 100 of FIG. 1 continues with optionally forming 110 a dummy gate stack to form the example resulting structure of FIG. 2E, in accordance with some embodiments. Recall that method 100 is primarily described herein in the context of a gate last transistor fabrication process flow, where the processing includes forming a dummy gate stack, performing the S/D processing, and then forming the final gate stack after the S/D regions have been processed. However, in other embodiments, the techniques may be performed using a gate first process flow. In such an example case, process 110 (forming a dummy gate stack) would not be performed, and thus, process 110 may be optional in some embodiments (such as those employing the gate first process flow). This is reflected with the alternative location for performing 114 final gate stack processing, which is shown as the optional gate first flow 100′ in FIG. 1, where performing 114 the final gate stack processing would instead occur at the location of box 110 in embodiments employing a gate first process flow, for example. However, the description of method 100 will continue using a gate last process flow, to allow for such a flow (which generally includes additional processing) to be adequately described.

Continuing with forming 110 a dummy gate stack, such a dummy gate stack (where employed) may include dummy gate dielectric 242 and dummy gate electrode 244, thereby forming the example resulting structure of FIG. 2E, in this example embodiment. In this example embodiment, dummy gate dielectric 242 (e.g., dummy oxide material) and dummy gate electrode 244 (e.g., dummy poly-silicon material) may be used for a replacement gate process. Note that side-wall spacers 250, referred to generally as gate spacers (or simply, spacers), on either side of the dummy gate stack were also formed, and such spacers 250 can be used to help determine the channel length and/or to help with replacement gate processes, for example. As can be understood based on this disclosure, the dummy gate stack (and spacers 250) can help define the channel region and source/drain (S/D) regions of each fin, where the channel region is below the dummy gate stack (as it will be located below the final gate stack), and the S/D regions are on either side of and adjacent to the channel region. Note that because the IC structures are being described in the context of forming finned transistors, the final gate stack will also be adjacent to either side of the fin, as the gate stack will reside along three walls of the finned channel regions, in embodiments employing a finned (e.g., FinFET) configuration.

Formation of the dummy gate stack may include depositing the dummy gate dielectric material 242 and dummy gate electrode material 244, patterning the dummy gate stack, depositing gate spacer material 250, and performing a spacer etch to form the structure shown in FIG. 2E, for example. Spacers 250 may include any suitable material, such as any suitable electrical insulator, dielectric, oxide (e.g., silicon oxide), and/or nitride (e.g., silicon nitride) material, as will be apparent in light of this disclosure. Note that in some embodiments, as previously described, the techniques described herein need not include forming a dummy gate stack, such that a final gate stack may be formed in the first instance. Regardless, the end structure will include the final gate stack described herein, as will be apparent in light of this disclosure. Also note that in some embodiments, a hardmask may be formed over the dummy gate stack (which may or may not also be formed over spacers 250) to protect the dummy gate stack during subsequent processing, for example. The previous relevant description of hardmask 210 is equally applicable to such a hardmask feature, where employed.

Method 100 of FIG. 1 continues with performing 112 source and drain (S/D) region processing to form the example resulting structure of FIG. 2F, in accordance with some embodiments. In this example embodiment, the S/D processing 112 included removing and replacing portions of fins 204 in the S/D regions to form S/D regions 260 as shown in FIG. 2F. In some embodiments, removing the portions of fins 204 (or the portions of replacement fins 230, where employed) in the S/D regions (the regions not covered by the dummy gate stack, in this example embodiment) may include any suitable techniques, such as one or more wet and/or dry etch processes, for example. Further, in some embodiments, forming the S/D regions 260 can be performing using any suitable techniques, such as one or more of the deposition processes described herein (e.g., CVD, MOCVD, ALD, PVD, MBE), and/or any other suitable processes as will be apparent in light of this disclosure. In some such embodiments, the S/D regions 260 may be formed using a selective deposition process, e.g., such that the S/D material only or significantly grows (or only grows in a monocrystalline structure) from the exposed semiconductor material of sub-fin portions 203, as can be understood based on this disclosure. Note that the S/D regions 260 are referred to herein as such for ease of description, but each S/D region may be either a source region or a drain region, such that the corresponding S/D region (on the other side of the channel region, and thus, on the other side of the dummy gate stack) is the other of the source region and drain region, thereby forming a source and drain region pair. For instance, as shown in FIG. 2F, there are four different S/D region 260 pairs.

In some embodiments, the S/D regions 260 may have different shapes and configurations, as will be apparent in light of this disclosure. For instance, in the example structure of FIG. 2F, the S/D regions include three-dimensional diamond shapes, with two top surfaces that are faceted (e.g., with {111} faceting) as shown. To provide another example structure, FIG. 2F′ is a blown-out portion of FIG. 2F, illustrating an alternative rounded S/D region 260′ that may be formed, in accordance with some embodiments. As shown, rounded S/D region 260′ includes a rounded and unfaceted top, and the rounded or curved S/D region 260′ also extends past the underlying sub-fin portion 203 in the X-axis direction. As can be understood based on this disclosure, S/D regions including any shape (such as the diamond shape of S/D regions 260 or the rounded shape of S/D region 260′) can benefit from the techniques described herein. To provide an additional configuration, FIG. 2F″ is a blown-out portion of FIG. 2F, illustrating a final S/D region that is alternatively formed using a cladding scheme, in accordance with some embodiments. For example, by not removing portions of fin 204 (or replacement fin 230, when employed) from the S/D regions, one or more cladding layers may be deposited on the fin to form the final S/D region. In the example embodiment of FIG. 2H″, cladding layer 260″ was formed on native fin 204 as shown to form the final S/D region. Thus, the final S/D regions can be formed using any suitable techniques and can include numerous different variations and configurations, as can be understood based on this disclosure. Note that the relevant description of S/D regions 260 herein (e.g., included materials and doping schemes) is equally applicable to features 260′ and 260″.

In some embodiments, S/D regions 260 may include any suitable semiconductor material as will be apparent in light of this disclosure, such as monocrystalline group IV and/or group III-V semiconductor material. For instance, a given S/D region 260 may include one of monocrystalline Si, SiGe, Ge, GaAs, InGaAs, AlGaAs, AlAs, InP, and so forth. In some embodiments, a given S/D region 260 may include n-type and/or p-type dopant (such as in one of the schemes described herein). Where present, the dopant may be included in a concentration in the range of 1E17 to 5E22 atoms per cubic cm or greater, for example. In some embodiments, a given S/D region 260 may include grading (e.g., increasing and/or decreasing) of the concentration of one or more materials within the feature, such as the grading of a semiconductor material component concentration and/or the grading of the dopant concentration, for example. For instance, in some such embodiments, the dopant concentration included in a given S/D region 260 may be graded such that it is lower near the corresponding channel region and higher near the corresponding S/D contact, which may be achieved using any suitable processing, such as tuning the amount of dopant in the reactant flow (e.g., during an in-situ doping scheme). In some embodiments, a given S/D region 260 may include a multilayer structure that includes at least two compositionally different material layers. In some embodiments, a given S/D region may be raised such that it extends higher than a corresponding channel region.

Note that the S/D regions 260 are all shown with the same patterning to merely assist with visual identification of the different features in the figures. However, the patterning/shading of any of the features in the figures is not intended to limit the present disclosure in any manner. Also note that S/D regions 260 are all shown as including the same material and sizes/shapes in the example structure of FIG. 2H, for ease of illustration; however, the present disclosure is not intended to be so limited. For example, in some embodiments, one of the S/D regions in a corresponding S/D region pair (such as region 260 on one side of the dummy gate stack) may be processed separately than the other S/D region in that pair (such as region 260 on the opposite side of the dummy gate stack), such that a corresponding S/D pair may include different material, dopant type, dopant concentration, sizes, shapes, and/or any other suitable difference as can be understood based on this disclosure. For instance, in the case of a TFET device, one of the S/D regions may include n-type doped semiconductor material and the other of the S/D regions may include p-type doped semiconductor material, to provide an example case, such that the n-type S/D region may be processed separately from the p-type S/D region. The separate processing may be achieved using any suitable techniques, such as masking off S/D regions not to be processed to allow processing of other S/D regions, and then masking off the other S/D regions to allow processing of the originally masked off S/D regions, for example. In some embodiments, a given S/D region may include the same or a similar material composition (e.g., within 1% different) as the corresponding/adjacent channel region. However, in other embodiments, a given S/D region may include a different material composition (e.g., at least 1, 2, 3, 4, 5, or 10% different) relative to the corresponding/adjacent channel region, for example.

Method 100 of FIG. 1 continues with performing 114 the final gate stack processing to form the example resulting structure of FIG. 2G, in accordance with some embodiments. As shown in FIG. 2G, the processing in this example embodiment included depositing interlayer dielectric (ILD) layer 270 on the structure of FIG. 2F, followed by planarization and/or polishing (e.g., CMP) to reveal the dummy gate stack. Note that ILD layer 270 is shown as transparent in the example structure of FIG. 2G to allow for the underlying features to be seen; however, the present disclosure is not intended to be so limited. Also note that ILD layer 270 may include a multilayer structure, even though it is illustrated as a single layer. Further note that in some cases, ILD layer 270 and STI material 220 may not include a distinct interface as shown in FIG. 2G, particularly where, e.g., the ILD layer 270 and STI material 220 include the same dielectric material. In some embodiments, the ILD layer 270 may include any desired electrical insulator, dielectric, oxide (e.g., silicon oxide), and/or nitride (e.g., silicon nitride) material, as will be apparent in light of this disclosure.

The gate stack processing, in this example embodiment, continued with removing the dummy gate stack (including dummy gate 244 and dummy gate dielectric 242) to allow for the final gate stack to be formed. Recall that in some embodiments, the formation of the final gate stack, which includes gate dielectric 282 and gate electrode 284, may be performed using a gate first flow (also called up-front hi-k gate). In such embodiments, the final gate stack processing may have been alternatively performed at box 110, instead of forming a dummy gate stack. However, in this example embodiment, the final gate stack is formed using a gate last flow (also called a replacement gate or replacement metal gate (RMG) process). Regardless of whether gate first or gate last processing is employed, the final gate stack can include gate dielectric 282 and gate electrode 284 as shown in FIG. 2G and described herein.

Note that when the dummy gate is removed, the channel region of fins 204 (or replacement material fins 230), which is the portion of the fins that were covered by the dummy gate stack, are exposed to allow for any desired processing of the channel regions of the fins. Such processing of the channel region may include various different techniques, such as removing and replacing the channel region with replacement material, doping the channel region of the fin as desired, forming the fin into one or more nanowires (or nanoribbons) for a gate-all-around (GAA) transistor configuration, cleaning/polishing the channel region, and/or any other suitable processing as will be apparent in light of this disclosure. For instance, finned channel region 206 is illustrated (which is the channel region of the right-most of the four original finned structures) and that finned channel region may be a portion of native fin 204 (or replacement material fin 230) and/or it may have been processed in any suitable manner (e.g., removed and replaced with other replacement material, doped in a desired manner, etc.). To provide another example, nanowire channel region 208 (which is the channel region of the left-most of the four original finned structures) may have been formed after the dummy gate was removed and the channel regions of the fins were exposed, by converting the finned structure at that location into the nanowires 208 shown using any suitable techniques, for example. For instance, the original finned channel region may have included a multilayer structure, where one or more of the layers were sacrificial and selective etch processing is performed to remove those sacrificial layers and release the nanowires 206. As shown in FIG. 2G, nanowire channel region 206 includes 2 nanowires (or nanoribbons) in this example case. However, a nanowire (or nanoribbon or GAA) transistor formed using the techniques disclosed herein may include any number of nanowires (or nanoribbons) such as 1, 3, 4, 5, 6, 7, 8, 9, 10, or more, depending on the desired configuration. In some embodiments, a nanowire or nanoribbon may be considered fin-shaped where the gate stack wraps around each fin-shaped nanowire or nanoribbon in a GAA transistor configuration.

As can be understood based on this disclosure, the channel region is at least below the gate stack, in this example embodiment. For instance, in the case of a finned transistor configuration, the channel region may be below and between the gate stack, as the stack is formed on three sides as is known in the art. However, if the transistor device were inverted and bonded to what will be the end substrate, then the channel region may be above the gate. Therefore, in general, the gate and channel relationship may include a proximate relationship (which may or may not include one or more intervening gate dielectric layers and/or other suitable layers), where the gate is near the channel region such that it can exert control over the channel region in an electrical manner, in accordance with some embodiments. Further, in the case of a nanowire (or nanoribbon or GAA) transistor configuration, the gate stack may completely surround each nanowire/nanoribbon in the channel region (or at least substantially surround each nanowire, such as surrounding at least 70, 80, or 90% of each nanowire). Further still, in the case of a planar transistor configuration, the gate stack may simply be above the channel region.

In some embodiments, a given channel region of a transistor device, such as channel region 206, may include monocrystalline group IV semiconductor material (e.g., Si, SiGe, Ge), group III-V semiconductor material (e.g., GaAs, InGaAs, InAs), and/or any other suitable material as will be apparent in light of this disclosure. In general, a given channel region may include at least one of silicon (Si), germanium (Ge), tin (Sn), indium (In), gallium (Ga), arsenic (As), phosphorous (P), and aluminum (Al), to provide some examples. In some embodiments, the channel region may be doped (e.g., with any suitable n-type and/or p-type dopant) or intrinsic/undoped (or nominally undoped), depending on the particular configuration. In some embodiments, a given channel region, such as channel region 206, may include grading (e.g., increasing and/or decreasing) of the concentration of one or more materials within the feature, such as the grading of a semiconductor material component concentration and/or the grading of the dopant concentration, for example. In some embodiments, a given channel region may include a multilayer structure that includes at least two compositionally different material layers.

Note that S/D regions 260 are adjacent to either side of a corresponding channel region, as can be seen in FIG. 2G, for example. More specifically, the S/D regions 260 are directly adjacent to a corresponding channel region, such that there are no intervening layers between either of the S/D regions and the channel region, in this example embodiment. However, the present disclosure is not intended to be so limited. Also note that the configuration/geometry of a transistor formed using the techniques described herein may primarily be described based on the shape of the respective channel region of that transistor. For instance, a nanowire (or nanoribbon or GAA) transistor may be referred to as such because it includes one or more nanowires (or nanoribbons) in the channel region of that transistor and because the gate stack (including the gate) wraps around (or at least substantially wraps around) each nanowire (or nanoribbon). However, the transistor type (e.g., MOSFET, TFET, FFFET, or other suitable type) may be described based on the doping and/or operating scheme of the source, channel, and drain regions, and thus those respective regions may be used to determine the type or classification of a given transistor, for example. For instance, MOSFET and TFET transistors may structurally be very similar (or the same), but they include different doping schemes (e.g., source-drain doping schemes for MOSFET of p-p or n-n versus p-n or n-p for TFET).

Continuing with performing 114 final gate stack processing, after the dummy gate has been removed and any desired channel region processing has been performed, the final gate stack can then be formed, in accordance with some embodiments. In this example embodiment, the final gate stack includes gate dielectric 282 and gate electrode 284, as shown in FIG. 2G. The gate dielectric 282 may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. In some embodiments, an annealing process may be carried out on the gate dielectric 282 to improve its quality when high-k dielectric material is used. The gate electrode 284 may include a wide range of materials, such as polysilicon or various suitable metals or metal alloys, such as aluminum (Al), tungsten (W), titanium (Ti), tantalum (Ta), copper (Cu), titanium nitride (TiN), or tantalum nitride (TaN), for example. In some embodiments, gate dielectric 282 and/or gate electrode 284 may include a multilayer structure of two or more material layers, for example. In some embodiments, gate dielectric 282 and/or gate electrode 284 may include grading (e.g., increasing and/or decreasing) the content/concentration of one or more materials in at least a portion of the feature(s). Additional layers may be present in the final gate stack, in some embodiments, such as one or more work-function layers or other suitable layers, for example. Note that although gate dielectric 282 is only shown below gate electrode 284 in the example embodiment of FIG. 2G, in other embodiments, the gate dielectric 282 may also be present on one or both sides of gate electrode 284, such that the gate dielectric 282 may also be between gate electrode 284 and one or both of spacers 250, for example. Numerous different gate stack configurations will be apparent in light of this disclosure.

Method 100 of FIG. 1 continues with performing 116 S/D contact processing to form the example resulting structure of FIG. 2I, in accordance with some embodiments. S/D contact processing 116, in this example embodiment, first included forming S/D contact trenches 290 above the S/D regions 260, as shown in FIG. 2H. In some such embodiments, the contact trenches 290 may be formed using any suitable techniques, such as performing one or more wet and/or dry etch processes to remove portions of ILD layer 270 as shown, and/or any other suitable processing as will be apparent in light of this disclosure. Such etch processing may be referred to as the S/D contact trench etch processing, or simply, contact trench etch processing. Further, in some such embodiments, the ILD may first be patterned such that areas that are not to be removed via the contact trench etch processing are masked off, for example. In some embodiments, one or more etch stop layers may have been formed on S/D regions 260 prior to performing the contact trench etch processing, to help with the controllability of the processing (e.g., to help stop the etching to help prevent the etching from consuming material of the S/D regions 260 in an undesired manner). In some such embodiments, the etch stop layer(s) may include insulator material that is dissimilar from the ILD 270 material (e.g., to provide relative etch selectivity) and/or material that that is resilient to the contact trench etch, such as a carbon-based layer (e.g., with carbon concentration in the range of 1-20%).

Continuing from the example structure of FIG. 2H to the example structure of FIG. 2I, S/D contact processing 116 includes forming S/D contacts 291 above respective S/D regions 260, in accordance with some embodiments. In the example structure of FIG. 2I, it can be understood that S/D contacts 291 are electrically connected to S/D regions 260, and in some cases, they may also be in physical contact with those S/D regions 260. In some embodiments, S/D contacts 291 may be formed using any suitable techniques, such as depositing metal or metal alloy (or other suitable electrically conductive material) in contact trenches 290. In some embodiments, S/D contact 291 formation may include silicidation, germanidation, III-V-idation, and/or annealing processes, for example, where such processing may be performed to form the intervening contact layer before forming the bulk contact metal structure, for instance. In some embodiments, S/D contacts 291 may include aluminum or tungsten, although any suitable conductive metal or alloy can be used, such as silver, nickel-platinum, or nickel-aluminum, for example. Generally, in some embodiments, one or more of the S/D contacts 291 may include a resistance reducing metal and a contact plug metal, or just a contact plug, for instance. Example contact resistance reducing metals include, for instance, nickel, aluminum, titanium, gold, gold-germanium, nickel-platinum, or nickel aluminum, and/or other such resistance reducing metals or alloys. Example contact plug metals include, for instance, aluminum, copper, nickel, platinum, titanium, or tungsten, or alloys thereof, although any suitably conductive contact metal or alloy may be used. In some embodiments, S/D contacts 291 may include one or more rare earth metals. Rare earth metals include the following elements: cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y). In some embodiments, S/D contacts 291 may employ low work-function metal material(s) and/or high work-function metal material(s), depending on the particular configuration. In some embodiments, additional layers may be present in the S/D contact regions, such as adhesion layers (e.g., titanium nitride) and/or liner or barrier layers (e.g., tantalum nitride), if so desired.

Method 100 of FIG. 1 continues with optionally forming 118 diffusion barrier layer 292 above the S/D contacts 291 and in contact trenches 290 to form the example resulting structure of FIG. 2J, in accordance with some embodiments. Note that process 118 is optional because diffusion barrier layer 292 is an optional layer that need not be employed in some embodiments. However, in this example embodiment, it is included for purposes of description. In some embodiments, diffusion barrier layer 292, where present, may be formed using any suitable deposition techniques (e.g., CVD, ALD, PVD). In some embodiments, the diffusion barrier layer 292, where present, may be formed in-situ (without air break) to prevent exposure of S/D contacts 291 to an oxygen-including environment, for example. In some embodiments, a given diffusion barrier layer 292, where present, may have a thickness (dimension in the vertical or Y-axis direction) in the range of 2-30 nm (or in a sub-range of 2-5, 2-10, 2-15, 2-20, 5-10, 5-15, 5-20, 5-30, 10-15, 10-20, or 10-30 nm), or any other suitable value or range as will be apparent in light of this disclosure.

In some embodiments, diffusion barrier layer 292 may be employed between a chromium-based oxygen barrier layer (where the oxygen barrier layer 293 is described in more detail below) and the underlying metal contact 291 to, for example, help prevent diffusion of the chromium into the material of the metal contact 291. In some such embodiments, the diffusion barrier layer 292 may include titanium (Ti), to provide an example. In some embodiments, a diffusion barrier layer may be employed between an iridium-based oxygen barrier layer (where the oxygen barrier layer 293 is described in more detail below) and the underlying metal contact 291 to, for example, help prevent diffusion of the iridium into the material of the metal contact 291. For instance, in embodiments where an iridium-based oxygen barrier layer is being used to protect a metal contact (e.g., S/D contact 291) including one or more rare earth metals, such ytterbium, erbium, and/or yttrium, it may be undesirable to form the iridium-based oxygen barrier layer directly on that rare earth metal-based contact, because the metal of the contact structure. Such intermixing and diffusion causes an intermetallic region that is undesirable, as it leads to degraded performance for the contact structure and/or can hurt the oxygen barrier properties of the iridium-based layer. Thus, in some such embodiments, diffusion barrier layer 292 can be employed to reduce or prevent such intermixing/diffusion. In embodiments where diffusion barrier layer 292 is employed between an iridium-based oxygen barrier layer and metal contact 291, the diffusion barrier layer may include at least one of rhenium (Re), tungsten (W), and tantalum (Ta), to provide some examples. For instance, such a diffusion barrier layer may help prevent rare earth metals (where included in the metal contact) from undesirably diffusing into the iridium-based oxygen barrier layer. In some embodiments, diffusion barrier layer 292 may include carbon (C), silver (Ag), hafnium (Hf), tantalum nitride (TaN), and/or titanium nitride (TiN) to act as a barrier and help prevent outdiffusion of the iridium from the oxygen barrier layer 293 (where it is iridium-based) into metal contact 291. Thus, in some embodiments, diffusion barrier layer 292 may include a multilayer structure having at least two compositionally different material layers, such as having a rare earth metal-based contact, a layer to help prevent outdiffusion of the rare earth metal above the contact, a layer to help prevent outdiffusion of iridium above the other layer, and then an iridium-based oxygen barrier layer above the layer that helps prevent outdiffusion of iridium, to provide an example scheme.

Method 100 of FIG. 1 continues with forming 120 oxygen barrier layer 293 above the S/D contacts 291 and in contact trenches 290 to form the example resulting structure of FIG. 2K, in accordance with some embodiments. In this example embodiment, as diffusion barrier layer 292 is present in the structure, oxygen barrier layer 293 is formed on that the diffusion barrier layer 292. However, in embodiments, where diffusion barrier layer 292 is not present, oxygen barrier layer 293 is formed directly on contact 291, as can be understood based on this disclosure. In some embodiments, oxygen barrier layer 293 may be formed using any suitable deposition techniques (e.g., CVD, ALD, PVD). In some embodiments, the oxygen barrier layer 293 may be formed in-situ (without air break) to prevent exposure of the underlying diffusion barrier layer 292 (where present) and/or S/D contacts 291 to an oxygen-including environment, for example. In some embodiments, a given oxygen barrier layer 293 may have a thickness (dimension in the vertical or Y-axis direction) in the range of 2-30 nm (or in a sub-range of 2-5, 2-10, 2-15, 2-20, 5-10, 5-15, 5-20, 5-30, 10-15, 10-20, or 10-30 nm), or any other suitable value or range as will be apparent in light of this disclosure. Note that, generally, dimensional values described herein, such as the thicknesses values of oxygen barrier layer 293, may be the max dimension of one or more features, the average dimension of one or more features, the dimension in a given plane, or some other suitable dimensional property, as can be understood based on this disclosure. In some embodiments, the oxygen barrier layer 293 includes chromium and/or iridium. Thus, in some embodiments, the oxygen barrier layer 293 may only include chromium and not iridium, only include iridium and not chromium, or include both chromium and iridium, for example. Moreover, in some embodiments, the oxygen barrier layer 293 may essentially consist of only chromium or iridium, such that it significantly only includes that single material (e.g., and may include trace amounts of one or more other materials, where such other materials may be present as a result of impurities or processing, for instance). Generally, the oxygen barrier layer 293 includes conductive material (e.g., a metal or metal alloy), such that it can remain in the end structure (e.g., as compared to employing a layer including electrical insulator material at the location of the oxygen barrier layer).

In embodiments where the oxygen barrier layer 293 is chromium-based (such that it includes chromium), the chromium-based layer may include only chromium (or otherwise essentially consist of chromium) or include a chromium-based alloy, for example. As can be understood based on this disclosure, chromium can be included in the oxygen barrier layer 293 to help reduce (or to eliminate) oxidation of the underlying metal contact 291. In embodiments where a chromium-based alloy is employed for oxygen barrier layer 293, the chromium may be alloyed with at least one of cobalt (Co), nickel (Ni), and molybdenum (Mo), to provide a few examples. In some such embodiments, the chromium-based alloy may have a chromium concentration (by atomic percentage) in the range of 1-50% (or in a subrange of 1-10, 1-20, 1-30, 1-40, 5-10, 5-20, 5-30, 5-40, 5-50, 10-20, 10-30, 10-40, 10-50, 20-30, 20-40, 20-50, or 30-50%), or any other suitable value or range as will be apparent in light of this disclosure. Further, in embodiments where the oxygen barrier layer 293 includes a chromium-based alloy, that chromium-based alloy may include less than 50, 40, 30, 25, 20, 15, 10, or 5% chromium concentration (by atomic percentage), for example. In some embodiments, oxygen barrier layer 293 (and/or diffusion barrier layer 292, where present), may include grading (e.g., increasing and/or decreasing) of the concentration of one or more materials within the feature, such as the grading of the chromium and/or iridium content within a given oxygen barrier layer, for example. In some embodiments, oxygen barrier layer 293 (and/or diffusion barrier layer 292, where present) may include a multilayer structure that includes at least two compositionally different material layers such as the multilayer diffusion barrier layer previously described that includes both a layer to help prevent outdiffusion of the metal contact material (e.g., rare earth metal) and a layer above that layer to help prevent outdiffusion of the oxygen barrier layer material (e.g., iridium), for example.

In embodiments where the oxygen barrier layer 293 is iridium-based (such that it includes iridium), the iridium-based layer may include only iridium (or otherwise essentially consist of iridium) or include an iridium-based alloy, for example. As can be understood based on this disclosure, iridium can be included in the oxygen barrier layer 293 to help reduce (or to eliminate) oxidation of the underlying metal contact 291. In embodiments where an iridium-based alloy is employed for oxygen barrier layer 293, the iridium may be alloyed with at least one of cobalt (Co), nickel (Ni), and hafnium (Hf), to provide a few examples. In some such embodiments, the chromium-based alloy may have any chromium concentration (by atomic percentage), such as a concentration in the range of 1-99% (or in a subrange of 1-25, 1-50, 1-75, 10-25, 10-50, 10-75, 10-99, 25-50, 25-75, 25-99, 50-75, or 50-99%), for example. For instance, in embodiments where the oxygen barrier layer 293 includes an iridium-based alloy, that iridium-based alloy may include less than or greater than 5, 10, 20, 30, 40, 50, 60, 70, 80, or 90% iridium concentration (by atomic percentage), depending on the given configuration. Note that in embodiments where the oxygen barrier layer 293 includes an iridium-hafnium alloy, the iridium concentration (by atomic percentage) may be selected to be in the range of 10-20%, for example. Also note that, generally, for any oxygen barrier layer including an alloy configuration (e.g., a chromium-based alloy and/or an iridium-based alloy), the oxygen barrier properties may be degraded. Therefore, in some embodiments, it may be desired to use a chromium layer or an iridium layer for the oxygen barrier layer 293 (such that the oxygen barrier layer is not a metal alloy). However, alloying may be desired from a cost perspective as, for example, iridium, is generally an expensive material (but such cost has to be balanced with alloy processing, which generally adds to and/or complicates the processing).

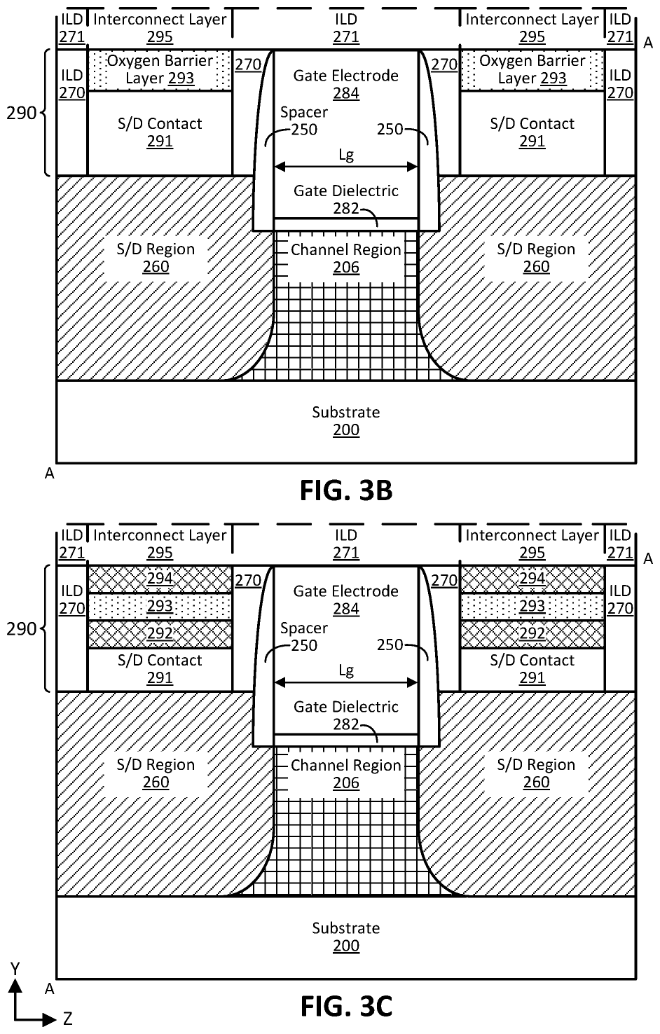

Method 100 of FIG. 1 continues with completing 122 integrated circuit (IC) processing as desired, in accordance with some embodiments. Such additional processing to complete the IC may include back-end or back-end-of-line (BEOL) processing to form one or more metallization layers and/or to interconnect the transistor devices formed during front-end or front-end-of-line (FEOL) processing, for example. Any other suitable processing may be performed, as will be apparent in light of this disclosure. For instance, in the example structures of FIGS. 3A-C, an example metallization layer is shown in dashed lines, which includes an additional layer of ILD material 271 and interconnect layer 295 formed in that additional ILD layer 271. The previous relevant description of ILD material 270 is equally applicable to ILD material 271. Interconnect layer 295 may include any suitable metal or metal alloy (or otherwise electrically conductive material), such as copper, to provide an example. The metallization layer or level is provided to help illustrate the location of the different contact metal contact cap layers shown in FIGS. 3A-C, where each cap layer includes oxygen barrier layer 293, and some of the cap layers include one or more diffusion barrier layers 292, 294, as will be described in more detail below.

FIG. 3A illustrates an example cross-sectional view along the plane A-A in FIG. 2K, in accordance with some embodiments. The cross-sectional view of FIG. 3A is provided to assist in illustrating different features of the structure of FIG. 2K. Therefore, the previous relevant description with respect to each similarly numbered feature is equally applicable to FIG. 3A. However, note that the dimensions of the features shown in FIG. 3A may differ relative to the features in FIG. 2K, for ease of illustration. Also note that some variations occur between the structures, such as the shape of spacers 250 and the shape of finned channel region 206, for example. Further note that channel region 206 shown in FIG. 3A is not native to substrate 200; however, in other embodiments, the channel region (and thus, the material of that channel region) is native to the substrate. Further still, note that the location of contact trenches 290 in which the S/D contacts 291 and overlying cap layers are formed is indicated on the left side of the structure. As shown in the example embodiment of FIG. 3A, the cap layer for the S/D contacts 291 each include oxygen barrier layer 293 and diffusion barrier layer 292 between the oxygen barrier layer 293 and the respective S/D contact 291. As is also shown, the oxygen barrier layer 293 is between the S/D contact 291 and the corresponding interconnect layer 295. As is also shown, diffusion barrier layer 292 is directly on S/D contact 291, in this example embodiment, such that oxygen barrier layer 293 is not directly on the corresponding S/D contact 291, but only above that S/D contact 291. Numerous other relative relationships will be apparent based on the figures.

FIG. 3B illustrates the cross-sectional view of FIG. 3A, showing a variation where the diffusion barrier layer 292 is not present in the contact cap layer, in accordance with some embodiments. As shown in FIG. 3B, diffusion barrier layer was not formed (e.g., optional process 118 was not performed), such that the oxygen barrier layer 293 is the only layer in the contact cap layer. In such an embodiment, the oxygen barrier layer 293 is formed directly on the corresponding S/D contact 291, as shown in FIG. 3B. FIG. 3C illustrates the cross-sectional view of FIG. 3A, showing a variation where an additional diffusion barrier layer 294 is present between the oxygen barrier layer 293 and interconnect layer 295, in accordance with some embodiments. In such an example embodiment, additional diffusion barrier layer 294 may have been formed in the S/D contact trenches 290 after forming oxygen barrier layer 293 via process 120, for example. Such additional processing may be similar to process 118 used to form diffusion barrier layer 292. The previous relevant description with respect to diffusion barrier layer 292 is equally applicable to additional diffusion barrier layer 294. For instance, in some embodiments, additional diffusion barrier layer 294 may include diffusion barrier material to help prevent outdiffusion of the oxygen barrier layer material (e.g., iridium) into the overlying metal interconnect 295, where such diffusion barrier material may include, for example, carbon (C), silver (Ag), hafnium (Hf), tantalum nitride (TaN), and/or titanium nitride (TiN). However, a main difference between the diffusion barrier layers 292 and 294 is their locations, as shown. For instance, diffusion barrier layer 292 is present between oxygen barrier layer 293 and a corresponding S/D contact 291 to help prevent intermixing of the chromium and/or iridium included in the oxygen barrier layer 293 (and/or other material included in layer 293) with the metal material(s) included in that S/D contact 291. However, diffusion barrier layer 294 is present between oxygen barrier layer 293 and a corresponding interconnect feature 295 to help prevent intermixing of the chromium and/or iridium included in the oxygen barrier layer 293 (and/or other material included in layer 293) with the metal material(s) included in that interconnect feature 295. Note that the patterning/shading of the various features is merely provided to assist in their visual identification within the figures and is not intended to limit this disclosure in any way.

In some embodiments, the length of gate electrode 284 (e.g., the dimension between spacers 250 in the Z-axis direction), which is indicated as Lg in FIGS. 3A-C, may be any suitable length as will be apparent in light of this disclosure. For instance, in some embodiments, the gate length may be in the range of 3-100 nm (e.g., 3-10, 3-20, 3-30, 3-50, 5-10, 5-20, 5-30, 5-50, 5-100, 10-20, 10-30, 10-50, 10-100, 20-30, 20-50, 20-100, or 50-100 nm), or any other suitable value or range as will be apparent in light of this disclosure. In some embodiments, the gate length may be less than a given threshold, such as less than 100, 50, 45, 40, 35, 30, 25, 20, 15, 10, 8, or 5 nm, or less than some other suitable threshold as will be apparent in light of this disclosure. In some embodiments, the techniques enable maintaining a desired device performance when scaling to such low thresholds, such as sub-50, sub-40, sub-30, or sub-20 nm thresholds, as can be understood based on this disclosure. Further, the techniques described herein may allow the gate length and the effective channel length (dimension between the S/D regions in the Z-axis direction) to be the same or approximately the same, in accordance with some embodiments. Thus, the gate length may approximate the effective channel length, in some such embodiments.

Note that the processes 102-122 of method 100 are shown in a particular order for ease of description. However, one or more of the processes 102-122 may be performed in a different order or may not be performed at all. For example, box 110 is an optional process that need not be performed in embodiments employing a gate first process flow, for example. Box 118 is also an optional process, as it need not be performed in embodiments that do not include a diffusion barrier layer for the oxygen barrier layer in the cap layer for a given metal contact. Recall that the techniques may be used to form a multitude of different transistor types and configurations. Although the techniques are primarily depicted and described herein in the context of employing a cap layer (including an oxygen barrier layer) for both of the S/D contacts of a given transistor, the present disclosure is not intended to be so limited, as the techniques may be used to benefit only one S/D contact of a given transistor, and not the other, in some embodiments. In addition, in some embodiments, the cap layer as variously described herein may be used in other IC structures to provide benefits for other metal features. For instance, the techniques described herein may be applied to employ an oxygen barrier layer for a metal gate or a metal interconnect, in accordance with some embodiments. Therefore, the present disclosure is not intended to limit the cap layer (including an oxygen barrier layer) as described herein for use with only S/D contacts, unless otherwise stated. Numerous variations and configurations will be apparent in light of the present disclosure.

Example System

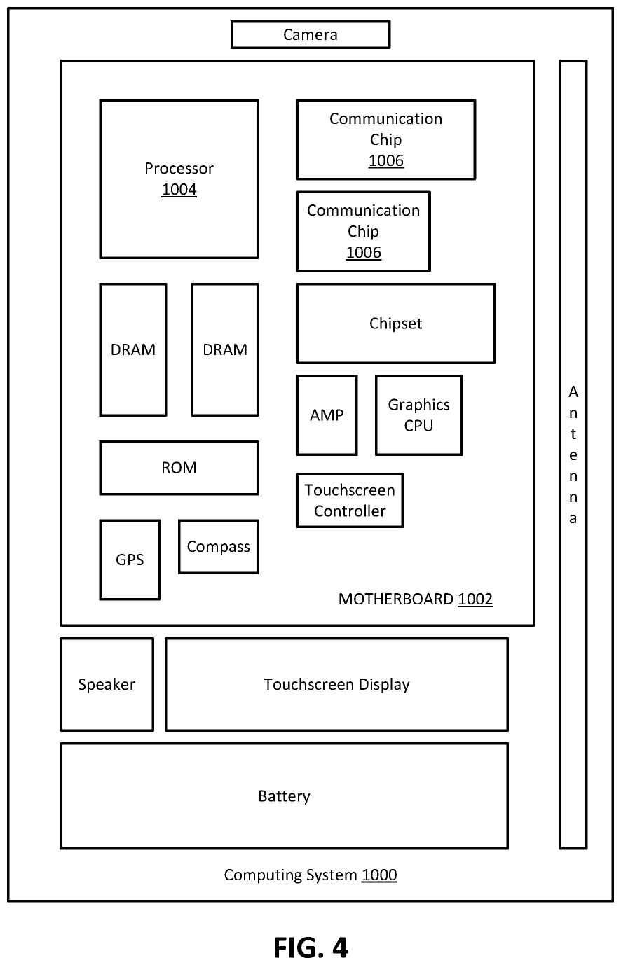

FIG. 4 illustrates a computing system 1000 implemented with integrated circuit structures and/or transistor devices formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1 is an integrated circuit (IC) including at least one transistor, the IC including: a channel region; a gate structure at least above the channel region; a source region adjacent the channel region; a drain region adjacent the channel region; a contact structure above the source region, the contact structure including metal material; and a first layer above the contact structure, the first layer including at least one of chromium and iridium.

Example 2 includes the subject matter of Example 1, wherein the first layer is directly on the contact structure, such that the at least one of chromium and iridium is in physical contact with the metal material included in the contact structure.

Example 3 includes the subject matter of Example 1 or 2, wherein the first layer has a vertical thickness in the range of 2 to 15 nanometers.

Example 4 includes the subject matter of any of Examples 1-3, wherein the first layer includes chromium.

Example 5 includes the subject matter of Example 4, wherein the first layer also includes at least one of cobalt, nickel, and molybdenum.

Example 6 includes the subject matter of Example 4 or 5, wherein the first layer includes chromium in a concentration of less than 30 percent by atomic percentage.

Example 7 includes the subject matter of Example 4, wherein the first layer essentially consists of chromium.

Example 8 includes the subject matter of any of Examples 4-7, further including a second layer between the contact structure and the first layer, the second layer including titanium.

Example 9 includes the subject matter of any of Examples 1-6, wherein the first layer includes iridium.

Example 10 includes the subject matter of Example 9, wherein the first layer also includes at least one of cobalt, nickel, and hafnium.

Example 11 includes the subject matter of Example 10, wherein the first layer includes iridium and hafnium with an iridium concentration between 10 and 20 percent by atomic percentage.

Example 12 includes the subject matter of Example 9, wherein the first layer essentially consists of iridium.

Example 13 includes the subject matter of any of Examples 9-12, further including a second layer between the contact structure and the first layer, the second layer including at least one of rhenium, tungsten, tantalum, hafnium, titanium, carbon, and silver. In such an example, the second layer may include a multilayer structure including at least two compositionally different material layers.

Example 14 includes the subject matter of Example 8 or Example 13, wherein the second layer has a thickness between the first layer and the contact structure in the range of 2 to 15 nanometers.

Example 15 includes the subject matter of any of Examples 1-14, wherein the contact structure includes at least one rare earth metal.

Example 16 includes the subject matter of any of Examples 1-15, wherein at least one of the source region and the drain region includes n-type doped monocrystalline semiconductor material.

Example 17 is a computing system including the subject matter of any of Examples 1-16.

Example 18 is an integrated circuit (IC) including at least one non-planar transistor, the IC including: a channel region; a gate structure at least above the channel region, wherein the channel region is between portions of the gate structure; a source region adjacent the channel region, the source region including n-type doped monocrystalline semiconductor material; a drain region adjacent the channel region, the drain region including n-type doped monocrystalline semiconductor material; a contact structure above the source region, the contact structure including at least one rare earth metal; and a first layer above the contact structure, the first layer including at least one of chromium and iridium.

Example 19 includes the subject matter of Example 18, wherein the n-type doped monocrystalline semiconductor material included in the source and drain regions is n-type doped monocrystalline silicon.

Example 20 includes the subject matter of Example 18 or 19, wherein the first layer has a vertical thickness in the range of 2 to 15 nanometers.

Example 21 includes the subject matter of any of Examples 18-20, wherein the first layer includes chromium.

Example 22 includes the subject matter of Example 21, wherein the first layer also includes at least one of cobalt, nickel, and molybdenum.

Example 23 includes the subject matter of Example 21 or 22, wherein the first layer includes chromium in a concentration of less than 30 percent by atomic percentage.

Example 24 includes the subject matter of Example 21, wherein the first layer essentially consists of chromium.

Example 25 includes the subject matter of any of Examples 21-24, wherein the first layer is directly on the contact structure, such that the chromium included in the first layer is in physical contact with the at least one rare earth metal included in the contact structure.

Example 26 includes the subject matter of any of Examples 18-23, wherein the first layer includes iridium.

Example 27 includes the subject matter of Example 26, wherein the first layer also includes at least one of cobalt, nickel, and hafnium.

Example 28 includes the subject matter of Example 27, wherein the first layer includes iridium and hafnium with an iridium concentration between 10 and 20 percent by atomic percentage.

Example 29 includes the subject matter of Example 26, wherein the first layer essentially consists of iridium.

Example 30 includes the subject matter of any of Examples 26-29, further including a second layer between the contact structure and the first layer, the second layer including at least one of rhenium, tungsten, tantalum, hafnium, titanium, carbon, and silver. In such an example, the second layer may include a multilayer structure including at least two compositionally different material layers.

Example 31 includes the subject matter of Example 30, wherein the second layer has a thickness in the range of 2 to 15 nanometers.

Example 32 includes the subject matter of any of Examples 18-31, further including an interconnect structure above the first layer, wherein the interconnect structure is electrically connected to the source region through the first layer and the contact structure.

Example 33 includes the subject matter of any of Examples 18-32, wherein the at least one transistor is an n-channel metal-oxide semiconductor field-effect transistor.

Example 34 is a mobile computing system including the subject matter of any of Examples 18-33.

Example 35 is a method of forming an integrated circuit (IC) including at least one transistor, the method including: forming a gate at least above a channel region; forming a source region adjacent the channel region; forming a drain region adjacent the channel region; forming a contact structure above the source region, the contact structure including metal material; and forming a first layer above the contact structure, the first layer including at least one of chromium and iridium.

Example 36 includes the subject matter of Example 35, wherein the first layer is formed directly on the contact structure, such that the at least one of chromium and iridium is in physical contact with the metal material included in the contact structure.

Example 37 includes the subject matter of Example 35 or 36, wherein the first layer has a thickness in the range of 2 to 15 nanometers.

Example 38 includes the subject matter of any of Examples 35-37, wherein the first layer includes chromium.

Example 39 includes the subject matter of Example 38, wherein the first layer also includes at least one of cobalt, nickel, and molybdenum.

Example 40 includes the subject matter of Example 38 or 39, wherein the first layer includes chromium in a concentration of less than 30 percent by atomic percentage.

Example 41 includes the subject matter of Example 38, wherein the first layer essentially consists of chromium.

Example 42 includes the subject matter of any of Examples 38-41, further including forming a second layer, the second layer between the contact structure and the first layer, the second layer including titanium.

Example 43 includes the subject matter of any of Examples 35-40, wherein the first layer includes iridium.

Example 44 includes the subject matter of Example 43, wherein the first layer also includes at least one of cobalt, nickel, and hafnium.

Example 45 includes the subject matter of Example 44, wherein the first layer includes iridium and hafnium with an iridium concentration between 10 and 20 percent by atomic percentage.

Example 46 includes the subject matter of Example 43, wherein the first layer essentially consists of iridium.

Example 47 includes the subject matter of any of Examples 43-46, further including forming a second layer, the second layer between the contact structure and the first layer, the second layer including at least one of rhenium, tungsten, tantalum, hafnium, titanium, carbon, and silver. In such an example, the second layer may include a multilayer structure including at least two compositionally different material layers.

Example 48 includes the subject matter of Example 42 or Example 47, wherein the second layer has a thickness in the range of 2 to 15 nanometers.

Example 49 includes the subject matter of any of Examples 35-48, wherein the contact structure includes at least one rare earth metal.

Example 50 includes the subject matter of any of Examples 35-49, wherein at least one of the source and drain region includes n-type doped monocrystalline semiconductor material.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. An integrated circuit (IC), comprising:
a semiconductor region;
a gate structure at least above the semiconductor region;
a source region adjacent the semiconductor region;
a drain region adjacent the semiconductor region;
a contact structure above the source region, the contact structure including metal material; and
a layer above the contact structure, the layer including at least one of chromium and iridium.

2. The IC of claim 1, wherein the layer is directly on the contact structure, such that the at least one of chromium and iridium is in physical contact with the metal material included in the contact structure.

3. The IC of claim 1, wherein the layer has a vertical thickness in the range of 2 to 15 nanometers.

4. The IC of claim 1, wherein the layer includes chromium.

5. The IC of claim 4, wherein the layer also includes at least one of cobalt, nickel, and molybdenum.

6. The IC of claim 4, wherein the layer includes chromium in a concentration of less than 30 percent by atomic percentage.

7. The IC of claim 4, wherein the layer essentially consists of chromium.

8. The IC of claim 4, wherein the layer is a first layer, the IC further comprising a second layer between the contact structure and the first layer, the second layer including titanium.

9. The IC of claim 1, wherein the layer includes iridium.

10. The IC of claim 9, wherein the layer also includes at least one of cobalt, nickel, and hafnium.

11. The IC of claim 10, wherein the layer includes iridium and hafnium with an iridium concentration between 10 and 20 percent by atomic percentage.

12. The IC of claim 9, wherein the layer essentially consists of iridium.

13. The IC of claim 9, wherein the layer is a first layer, the IC further comprising a second layer between the contact structure and the first layer, the second layer including at least one of rhenium, tungsten, tantalum, hafnium, titanium, carbon, and silver.

14. The IC of claim 13, wherein the second layer has a thickness between the first layer and the contact structure in the range of 2 to 15 nanometers.

15. The IC of claim 1, wherein the contact structure includes at least one rare earth metal, and wherein at least one of the source region and the drain region includes n-type doped monocrystalline semiconductor material.

16. (canceled)

17. (canceled)

18. An integrated circuit (IC) including at least one non-planar transistor, the IC comprising:
a non-planar semiconductor region;
a gate structure on top and sides of the non-planar semiconductor region, wherein the semiconductor region is between portions of the gate structure, or the gate structure wraps around one or more nanowires or nanoribbons included in the semiconductor region;
a source region adjacent the semiconductor region, the source region including n-type doped monocrystalline semiconductor material;
a drain region adjacent the semiconductor region, the drain region including n-type doped monocrystalline semiconductor material;
a contact structure above the source or drain region, the contact structure including at least one rare earth metal; and
a layer above the contact structure, the layer including at least one of chromium and iridium.

19. The IC of claim 18, wherein the n-type doped monocrystalline semiconductor material included in the source and drain regions is n-type doped monocrystalline silicon.

20. (canceled)

21. The IC of claim 18, wherein the layer is a first layer, the IC further comprising a second layer between the contact structure and the first layer, the second layer including at least one of rhenium, tungsten, tantalum, hafnium, titanium, carbon, and silver.

22. The IC of claim 18, further comprising an interconnect structure above the first layer, wherein the interconnect structure is electrically connected to the source region through the first layer and the contact structure.

23. A method of forming an integrated circuit (IC), the method comprising:
forming a gate at least above a semiconductor region;
forming a source region adjacent the semiconductor region;
forming a drain region adjacent the semiconductor region;
forming a contact structure above the source region, the contact structure including metal material; and
forming a first layer above the contact structure, the first layer including at least one of chromium and iridium.

24. (canceled)

25. (canceled)
